(19) United States
(12) Patent Application Publication
(10) Pub. No.: US 2018/0370184 A1
(43) Pub. Date: Dec. 27, 2018

(54) OPTICAL ANISOTROPIC LAYER AND MANUFACTURING METHOD THEREFOR, OPTICAL ANISOTROPIC LAMINATE, AND CIRCULARLY POLARIZING PLATE

(71) Applicant: ZEON CORPORATION, Chiyoda-ku, Tokyo (JP)

(72) Inventors: Manabu ITO, Tokyo (JP); Kazuhiro OSATO, Tokyo (JP)

(73) Assignee: ZEON CORPORATION, Chiyoda-ku, Tokyo (JP)

(21) Appl. No.: 16/062,215

(22) PCT Filed: Dec. 14, 2016
(86) PCT No.: PCT/JP2016/087277

§ 371 Date: Jun. 14, 2018

(30) Foreign Application Priority Data
Dec. 25, 2015 (JP) 2015-253671

(51) Int. Cl. B32B 7/02; C09K 19/38; G02B 5/30; G02F 1/13363; H01L 51/50; H05B 33/02

(52) U.S. Cl. CPC B32B 7/02; C09K 19/38; H05B 33/02; G02F 1/13363; H01L 51/50; G02B 5/30

(57) ABSTRACT

An optically anisotropic layer obtained by curing a liquid crystal composition containing a photopolymerizable liquid crystal compound, wherein a ratio of the photopolymerizable liquid crystal compound in the optically anisotropic layer is 25% by weight or less, and absorption values of the optically anisotropic layer satisfy specific relationship, the values being at local maximum absorption wavelengths for polarized light parallel to an orientation direction of the optically anisotropic layer and at local maximum absorption wavelengths for polarized light perpendicular to the orientation direction of the optically anisotropic layer within each of a first wavelength range of 230 nm or more and less than 300 nm and a second wavelength range of 300 nm or more and 400 nm or less.

### FIELD

The present invention relates to an optically anisotropic layer and a method for producing the same; an optically anisotropic layered body including the optically anisotropic layer; and a circularly polarizing plate including the optically anisotropic layer or the optically anisotropic layered body.

### BACKGROUND

In prior art, phase difference films such as a λ/4 wave plate using a liquid crystal compound have been known. In recent years, of the phase difference films, a phase difference film with reverse wavelength distribution has been investigated to uniformly exert an optical action within a wide wavelength range. In order to realize such a phase difference film with reverse wavelength distribution, use as a phase difference film of an optically anisotropic layer produced using a liquid crystal composition containing a liquid crystal compound with reverse wavelength distribution has been proposed (Patent Document 1).

### CITATION LIST

### Patent Literature

Patent Literature 1: International Publication No. WO2014/65243

### SUMMARY

### Technical Problem

As described above, the optically anisotropic layer with reverse wavelength distribution have been successfully produced in the prior art technique. However, it is difficult to suppress a change of reverse wavelength distribution due to a durability test of the optically anisotropic layer. Specifically, when the prior-art optically anisotropic layer with reverse wavelength distribution is subjected to the durability test, a difference between the in-plane retardation at a short wavelength and the in-plane retardation at a long wavelength is decreased. Therefore, it is difficult to uniformly exert the optical action within a wide wavelength range.

The present invention has been made in view of the aforementioned problems. An object of the present invention is to provide an optically anisotropic layer with favorable reverse wavelength distribution before and after a durability test and a method for producing the same; an optically anisotropic layered body having the optically anisotropic layer; and a circularly polarizing plate having the optically anisotropic layer or the optically anisotropic layered body.

### Solution to Problem

The present inventor has intensively studied to solve the aforementioned problems. As a result, the inventor has found that an optically anisotropic layer generally has two local maximum absorption wavelengths corresponding to a photopolymerizable liquid crystal compound that may be a material for the optically anisotropic layer within a range of 230 nm to 400 nm; a molecule of a photopolymerizable liquid crystal compound that may be a material for an optically anisotropic layer with reverse wavelength distribution generally has a main chain mesogen and a side chain mesogen bonded to the main chain mesogen; when an absorbance corresponding to the main chain mesogen and an absorbance corresponding to the side chain mesogen satisfy a specific relationship in each of the local maximum absorption wavelengths, favorable reverse wavelength distribution is obtained; when an optical layered body contains a residual monomer in a large amount, a change of reverse wavelength distribution due to a durability test is large; when curing is performed with ultraviolet light (UV) under specific conditions, the amount of the residual monomer in the optically anisotropic layer is decreased, and in particular, when the optically anisotropic layer is heated during curing with UV, a photoreaction is promoted to significantly decrease the amount of the residual monomer. As a result, production of an optically anisotropic layer in which favorable reverse wavelength distribution is maintained even after the durability test has become possible.

That is, the present invention is as follows.

<1> An optically anisotropic layer obtained by curing a liquid crystal composition containing a photopolymerizable liquid crystal compound, wherein

a ratio of the photopolymerizable liquid crystal compound in the optically anisotropic layer is 25% by weight or less,

the optically anisotropic layer has a local maximum absorption wavelength for polarized light parallel to an orientation direction of the optically anisotropic layer and a local maximum absorption wavelength for polarized light perpendicular to the orientation direction of the optically anisotropic layer within each of a first wavelength range of 230 nm or more and less than 300 nm and a second wavelength range of 300 nm or more and 400 nm or less, and

an absorbance ε₁ₘ that is an absorbance of the optically anisotropic layer at the local maximum absorption wavelength for the polarized light parallel to the orientation direction of the optically anisotropic layer within the first wavelength range,

an absorbance ε₁ₛ that is an absorbance of the optically anisotropic layer at the local maximum absorption wavelength for the polarized light perpendicular to the orientation direction of the optically anisotropic layer within the first wavelength range,

an absorbance ε₂ₘ that is an absorbance of the optically anisotropic layer at the local maximum absorption wavelength for the polarized light parallel to the orientation direction of the optically anisotropic layer within the second wavelength range, and

an absorbance ε₂ₛ that is an absorbance of the optically anisotropic layer at the local maximum absorption wavelength for the polarized light perpendicular to the orientation direction of the optically anisotropic layer within the second wavelength range satisfy the following expressions (1) and (2):

1.30<ε₁ₘ/ε₁ₛ<1.70 (1), and

0.25<ε₂ₘ/ε₂ₛ<0.70 (2).

<2> The optically anisotropic layer according to <1>, wherein

an in-plane retardation Re(A450) of the optically anisotropic layer at a wavelength of 450 nm, an in-plane retardation Re(A550) of the optically anisotropic layer at a wavelength of 550 nm, and an in-plane retardation Re(A650) of the optically anisotropic layer at a wavelength of 650 nm satisfy the following expressions (3) and (4):

0.70<Re(A450)/Re(A550)<1.00 (3), and

1.00<Re(A650)/Re(A550)<1.20 (4).

<3> The optically anisotropic layer according to <1> or <2>, wherein

the photopolymerizable liquid crystal compound has a side chain mesogen represented by the following formula (A):

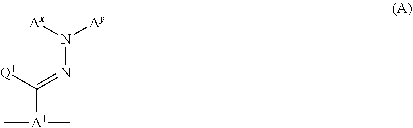

### (in the Formula (A),

A^{x} is an organic group of 2 to 30 carbon atoms having at least one aromatic ring selected from the group consisting of an aromatic hydrocarbon ring and an aromatic heterocyclic ring,

A^{y} is a hydrogen atom, an alkyl group of 1 to 20 carbon atoms optionally having a substituent, an alkenyl group of 2 to 20 carbon atoms optionally having a substituent, a cycloalkyl group of 3 to 12 carbon atoms optionally having a substituent, an alkynyl group of 2 to 20 carbon atoms optionally having a substituent, —C(═O)—R³, —SO₂—R⁴, —C(═S)NH—R⁹, or an organic group of 2 to 30 carbon atoms having at least one aromatic ring selected from the group consisting of an aromatic hydrocarbon ring and an aromatic heterocyclic ring, wherein R³ is an alkyl group of 1 to 20 carbon atoms optionally having a substituent, an alkenyl group of 2 to 20 carbon atoms optionally having a substituent, a cycloalkyl group of 3 to 12 carbon atoms optionally having a substituent, or an aromatic hydrocarbon ring group of 5 to 12 carbon atoms; R⁴ is an alkyl group of 1 to 20 carbon atoms, an alkenyl group of 2 to 20 carbon atoms, a phenyl group or a 4-methylphenyl group; R⁹ is an alkyl group of 1 to 20 carbon atoms optionally having a substituent, an alkenyl group of 2 to 20 carbon atoms optionally having a substituent, a cycloalkyl group of 3 to 12 carbon atoms optionally having a substituent, or an aromatic group of 5 to 20 carbon atoms optionally having a substituent; the aromatic ring that A^{x} and A^{y} have may have a substituent; and A^{x} and A^{y} may form a ring together,

A¹ is a trivalent aromatic group optionally having a substituent, and

Q¹ is a hydrogen atom or an alkyl group of 1 to 6 carbon atoms optionally having a substituent).

<4> The liquid crystal composition according to any one of <1> to <3>, wherein the photopolymerizable liquid crystal compound is represented by the following Formula (I):

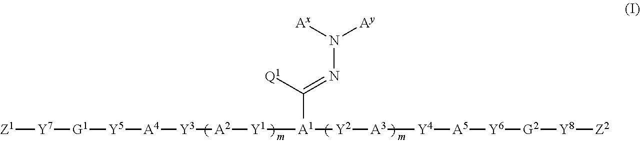

### (in the Formula (I),

Y¹ to Y⁸ are each independently a chemical single bond, —O—, —S—, —O—C(═O)—, —C(═O)—O—, —O—C(═O)—O—, —NR¹—C(═O)—, —C(═O)—NR¹—, —O—C(═O)—NR¹—, —NR¹—C(═O)—O—, —NR¹—C(═O)—NR¹—, —O—NR¹—, or —NR¹—O—, wherein R¹ is a hydrogen atom or an alkyl group of 1 to 6 carbon atoms;

G¹ and G² are each independently a divalent aliphatic group of 1 to 20 carbon atoms optionally having a substituent; the aliphatic groups may have one or more per one aliphatic group of —O—, —S—, —O—C(═O)—, —C(═O)—O—, —O—C(═O)—O—, —NR²—C(═O)—, —C(═O)—NR²—, —NR²—, or —C(═O)— inserted therein; provided that a case where two or more —O— or —S— groups are each adjacently inserted are excluded, wherein R² is a hydrogen atom or an alkyl group of 1 to 6 carbon atoms;

Z¹ and Z² are each independently an alkenyl group of 2 to 10 carbon atoms optionally being substituted by a halogen atom;

A^{x} is an organic group of 2 to 30 carbon atoms having at least one aromatic ring selected from the group consisting of an aromatic hydrocarbon ring and an aromatic heterocyclic ring;

A^{y} is a hydrogen atom, an alkyl group of 1 to 20 carbon atoms optionally having a substituent, an alkenyl group of 2 to 20 carbon atoms optionally having a substituent, a cycloalkyl group of 3 to 12 carbon atoms optionally having a substituent, an alkynyl group of 2 to 20 carbon atoms optionally having a substituent, —C(═O)—R³, —SO₂—R⁴, —C(═S)NH—R⁹, or an organic group of 2 to 30 carbon atoms having at least one aromatic ring selected from the group consisting of an aromatic hydrocarbon ring and an aromatic heterocyclic ring, wherein R³ is an alkyl group of 1 to 20 carbon atoms optionally having a substituent, an alkenyl group of 2 to 20 carbon atoms optionally having a substituent, a cycloalkyl group of 3 to 12 carbon atoms optionally having a substituent, or an aromatic hydrocarbon ring group of 5 to 12 carbon atoms; R⁴ is an alkyl group of 1 to 20 carbon atoms, an alkenyl group of 2 to 20 carbon atoms, a phenyl group, or a 4-methylphenyl group; R⁹ is an alkyl group of 1 to 20 carbon atoms optionally having a substituent, an alkenyl group of 2 to 20 carbon atoms optionally having a substituent, a cycloalkyl group of 3 to 12 carbon atoms optionally having a substituent, or an aromatic group of 5 to 20 carbon atoms optionally having a substituent; the aromatic ring that A^{x} and A^{y} have may have a substituent; and A^{x} and A^{y} may form a ring together;

A1 is a trivalent aromatic group optionally having a substituent;

A² and A³ are each independently a divalent alicyclic hydrocarbon group of 3 to 30 carbon atoms optionally having a substituent;

A⁴ and A⁵ are each independently a divalent aromatic group of 6 to 30 carbon atoms optionally having a substituent;

Q¹ is a hydrogen atom or an alkyl group of 1 to 6 carbon atoms optionally having a substituent; and

m is 0 or 1).

<5> The optically anisotropic layer according to any one of <1> to <4>, wherein the photopolymerizable liquid crystal compound has a CN point of 25° C. or higher and 120° C. or lower.
<6> The optically anisotropic layer according to any one of <1> to <5>, being a λ/4 wave plate.
<7> An optically anisotropic layered body comprising the optically anisotropic layer according to any one of <1> to <6>, and a phase difference layer, wherein

a refractive index nx of the phase difference layer in a direction which gives a maximum refractive index among in-plane directions, a refractive index ny of the phase difference layer in a direction which is one of the in-plane directions and is orthogonal to the direction of the nx, and a refractive index nz of the phase difference layer in the thickness direction of the layer satisfy nz>nx≥ny.

<8> The optically anisotropic layered body according to <7>, wherein

the optically anisotropic layer is a λ/4 wave plate, and

an in-plane retardation Re(B550) of the phase difference layer at a wavelength of 550 nm and a retardation Rth(B550) in a thickness direction of the phase difference layer at a wavelength of 550 nm satisfy the following formulae (5) and (6):

Re(B550)≤10 nm (5), and

−100 nm≤Rth(B550)≤−20 nm (6).

<9> A circularly polarizing plate comprising the optically anisotropic layer according to any one of <1> to <6> or the optically anisotropic layered body according to <7> or <8>, and a linear polarizer.
<10> A method for producing the optically anisotropic layer according to any one of <1> to <6>, comprising:

a step of applying the liquid crystal composition onto a substrate to obtain a layer of the liquid crystal composition;

a step of orienting the photopolymerization liquid crystal compound contained in the layer of the liquid crystal composition; and

a step of curing the liquid crystal composition.

### Advantageous Effects of Invention

According to the present invention, there can be provided an optically anisotropic layer with favorable reverse wavelength distribution before and after a durability test and a method for producing the same; an optically anisotropic layered body having the optically anisotropic layer; and a circularly polarizing plate having the optically anisotropic layer or the optically anisotropic layered body.

### BRIEF DESCRIPTION OF DRAWINGS

FIG. 1 is a schematic diagram schematically illustrating a state of the step (III) of curing a layer of a liquid crystal composition formed on a substrate film to obtain an optically anisotropic layer in an example of a method for producing the optically anisotropic layer.

### DESCRIPTION OF EMBODIMENTS

Hereinafter, the present invention will be described in detail with reference to examples and embodiments. However, the present invention is not limited to the following examples and embodiments and may be freely modified and practiced without departing from the scope of claims of the present invention and the scope of their equivalents.

In the following description, a “long-length” article means an article having a length that is 5 or more times the width, and preferably an article having a length that is 10 or more times the width, and specifically means an article having a length that allows an article to be wound up into a roll shape and stored or transported.

In the following description, “substrate”, “polarizing plate”, and “wave plate” include not only a rigid member, but also a flexible member, such as, for example, a resin film, unless otherwise specified.

In the following description, an in-plane retardation Re of a layer refers to a value represented by Re=(nx−ny)×d, unless otherwise specified. A retardation Rth in a thickness direction of a layer refers to a value represented by Rth=[{nx+ny}/2]−nz]×d, unless otherwise specified. Herein, nx represents a refractive index in a direction which, among directions perpendicular to the thickness direction of the layer (in-plane directions), gives the maximum refractive index, ny represents a refractive index in a direction which is one of the in-plane directions and is orthogonal to the direction of nx, nz represents a refractive index in the thickness direction of the layer, and d represents the thickness of the layer. These retardations may be measured by commercially available phase difference meters or using the Senarmont method.

In the following description, the term “(meth)acrylate” includes both “acrylate” and “methacrylate” and the term “(meth)acryl” includes both “acryl” and “methacryl”, unless otherwise specified.

In the following description, the slow axis of a layer represents a slow axis in an in-plane direction of the layer, unless otherwise specified.

In the following description, directions of elements being “parallel” and “perpendicular” may allow an error within the range of not impairing the advantageous effects of the present invention, for example, within a range of ±5°, unless otherwise specified.

In the following description, unless otherwise specified, the term “reverse wavelength distribution” refers to properties in which the in-plane retardation Re(450) at the wavelength of 450 nm, the in-plane retardation Re(550) at the wavelength of 550 nm, and the in-plane retardation Re(650) at the wavelength of 650 nm satisfy the following expressions (7) and (8):

Re(450)/Re(550)<1.00 (7), and

Re(650)/Re(550)>1.00 (8).

Unless otherwise specified, a front direction of a surface in the following description means a normal direction of the surface, and specifically refers to a direction of a polar angle of 0° and an azimuth angle of 0° with respect to the surface.

Unless otherwise specified, an inclined direction of a surface in the following description means a direction that is not parallel to or perpendicular to the surface, and specifically refers to a direction at a range of a polar angle with respect to the surface of larger than 0° and less than 90°.

[1. Structure and Properties of Optically Anisotropic Layer]

The optically anisotropic layer of the present invention is a layer obtained by curing a liquid crystal composition containing a photopolymerizable liquid crystal compound. The optically anisotropic layer is a layer formed of a cured product obtained by curing the liquid crystal composition. The optically anisotropic layer usually contains cured liquid crystal molecules obtained from the photopolymerizable liquid crystal compound. The “cured liquid crystal molecules” mean molecules of a solidified compound that is obtained by solidifying the compound while the state of exhibiting the liquid crystal phase is maintained, wherein the compound is capable of exhibiting a liquid crystal phase. The cured liquid crystal molecules contained in the optically anisotropic layer are usually a polymer obtained by polymerizing the photopolymerizable liquid crystal compound. Therefore, the optically anisotropic layer is usually a layer of a resin that contains the polymer obtained by polymerizing the photopolymerizable liquid crystal compound and if necessary, may contain an optional component. The optically anisotropic layer has optical anisotropy in accordance with the orientation state of the cured liquid crystal molecules.

Since the optically anisotropic layer has optical anisotropy as described above, the optically anisotropic layer has dichroism. Therefore, the absorbance of the optically anisotropic layer for polarized light parallel to the orientation direction of the optically anisotropic layer is usually different from the absorbance of the optically anisotropic layer for polarized light perpendicular to the orientation direction of the optically anisotropic layer. The “orientation direction of the optically anisotropic layer” refers to the orientation direction of the cured liquid crystal molecules contained in the optically anisotropic layer, and is usually parallel to the orientation direction of the photopolymerizable liquid crystal compound contained in the liquid crystal composition before curing. The “polarized light parallel to the orientation direction” is linearly polarized light of which the vibration direction of electric field is parallel to the orientation direction. The “polarized light perpendicular to the orientation direction” is linearly polarized light of which the vibration direction of electric field is perpendicular to the orientation direction. When the photopolymerizable liquid crystal compound is a liquid crystal compound containing a main chain mesogen and a side chain mesogen in the molecule, the absorbance of the optically anisotropic layer for polarized light parallel to the orientation direction of the optically anisotropic layer corresponds to the main chain mesogen, and the absorbance of the optically anisotropic layer for polarized light perpendicular to the orientation direction of the optically anisotropic layer corresponds to the side chain mesogen.

The optically anisotropic layer generally has a local maximum absorption wavelength within each of a first wavelength range of 230 nm or more and less than 300 nm and a second wavelength range of 300 nm or more and 400 nm or less. Therefore, the optically anisotropic layer has a local maximum absorption wavelength for the polarized light parallel to the orientation direction of the optically anisotropic layer and a local maximum absorption wavelength for the polarized light perpendicular to the orientation direction of the optically anisotropic layer within the first wavelength range. Further, the optically anisotropic layer has a local maximum absorption wavelength for the polarized light parallel to the orientation direction of the optically anisotropic layer and a local maximum absorption wavelength for the polarized light perpendicular to the orientation direction of the optically anisotropic layer within the second wavelength range. There is usually one local maximum absorption wavelength for the polarized light parallel to the orientation direction of the optically anisotropic layer within each of the first wavelength range and the second wavelength range. There is usually one local maximum absorption wavelength for the polarized light perpendicular to the orientation direction of the optically anisotropic layer within each of the first wavelength range and the second wavelength range. With regard to the optically anisotropic layer of the present invention, absorbances ε₁ₘ, ε₁ₛ, ε₂ₘ, and ε₂ₛ at the local maximum absorption wavelength satisfy the following expressions (1) and (2):

1.30<ε₁ₘ/ε₁ₛ<1.70 (1), and

0.25<ε₂ₘ/ε₂ₛ<0.70 (2).

The absorbances ε₁ₘ, ε₁ₛ, ε₁ₘ, and ε₂ₛ in the expressions (1) and (2) mean as follows.

The absorbance ε₁ₘ is an absorbance of the optically anisotropic layer at the local maximum absorption wavelength for the polarized light parallel to the orientation direction of the optically anisotropic layer within the first wavelength range.

The absorbance ε₁ₛ is an absorbance of the optically anisotropic layer at the local maximum absorption wavelength for the polarized light perpendicular to the orientation direction of the optically anisotropic layer within the first wavelength range.

The absorbance ε₂ₘ is an absorbance of the optically anisotropic layer at the local maximum absorption wavelength for the polarized light parallel to the orientation direction of the optically anisotropic layer within the second wavelength range.

The absorbance ε₂ₛ is an absorbance of the optically anisotropic layer at the local maximum absorption wavelength for the polarized light perpendicular to the orientation direction of the optically anisotropic layer within the second wavelength range.

The absorbances ε₁ₘ, ε₁ₛ, ε₂ₘ, and ε₂ₛ may be measured by a spectrophotometer (for example, “V-7200” manufactured by JASCO Corporation, etc.).

The expressions (1) and (2) described above will be described in detail. The dichroic ratio ε₁ₘ/ε₁ₛ of the absorbances within the first wavelength range is usually higher than 1.30, preferably higher than 1.35, and further preferably higher than 1.40, and is usually lower than 1.70, preferably lower than 1.60, and further preferably lower than 1.50. The dichroic ratio ε₂ₘ/ε₂ₛ of the absorbances within the second wavelength range is usually higher than 0.25, and is usually lower than 0.70, preferably lower than 0.68, and further preferably lower than 0.66.

The optically anisotropic layer according to the present invention wherein the dichroic ratios ε₁ₘ/ε₁ₛ and ε₂ₘ/ε₂ₛ of the absorbances fall within the aforementioned ranges can have favorable reverse wavelength distribution. The optically anisotropic layer having such favorable reverse wavelength distribution can exhibit a higher in-plane retardation with regard to transmitted light having a longer wavelength as compared with transmitted light having a shorter wavelength. Therefore, since the optically anisotropic layer has favorable reverse wavelength distribution, the optically anisotropic layer can uniformly exhibit a function of an optical film such as a λ/4 wave plate at a wide wavelength band.

The favorable reverse wavelength distribution of the optically anisotropic layer specifically refers to the wavelength distribution wherein the in-plane retardation Re(A450) of the optically anisotropic layer at a wavelength of 450 nm, the in-plane retardation Re(A550) of the optically anisotropic layer at a wavelength of 550 nm, and the in-plane retardation Re(A650) of the optically anisotropic layer at a wavelength of 650 nm satisfy the following expressions (3) and (4):

0.70<Re(A450)/Re(A550)<1.00 (3), and

1.00<Re(A650)/Re(A550)<1.20 (4).

More specifically, Re(A450)/Re(A550) is preferably higher than 0.70, further preferably higher than 0.74, and particularly preferably higher than 0.78, and is preferably lower than 1.00, further preferably lower than 0.95, and particularly preferably lower than 0.90. Further, Re(A650)/Re(A550) is preferably higher than 1.00, further preferably higher than 1.02, and particularly preferably higher than 1.04, and is preferably lower than 1.20, and further preferably lower than 1.19. The optically anisotropic layer wherein Re(A450)/Re(A550) and Re (A650)/Re(550) fall within the aforementioned ranges can easily exert the optical function of the optically anisotropic layer in a uniform manner at a wide wavelength region.

As a method for setting the dichroic ratios ε₁ₘ/ε₁ₛ and ε₂ₘ/ε₂ₛ of absorbances of the optically anisotropic layer within the aforementioned ranges, a procedure including appropriately selecting the photopolymerizable liquid crystal compound, appropriately controlling the orientation of the photopolymerizable liquid crystal compound in the liquid crystal composition before curing, or the like may be employed. In order to maintain the favorable reverse wavelength distribution of the optically anisotropic layer after a durability test, it may become important to set the ratio of a residual monomer, to be described later, within a specific range.

Since the optically anisotropic layer is formed of the cured product obtained by curing the liquid crystal composition containing the photopolymerizable liquid crystal compound, the optically anisotropic layer may contain the photopolymerizable liquid crystal compound. In the optically anisotropic layer, the ratio of the photopolymerizable liquid crystal compound is low. Hereinafter, the ratio of the photopolymerizable liquid crystal compound in the optically anisotropic layer is appropriately referred to as “residual monomer ratio”. When the weight of the optically anisotropic layer is 100% by weight, the specific residual monomer ratio of the optically anisotropic layer is usually 25% by weight or less, preferably 20% by weight or less, more preferably 10% by weight or less, and particularly preferably 6% by weight or less. The lower limit of the residual monomer ratio is ideally 0% by weight, but may be 2% by weight or more.

The residual monomer ratio of the optically anisotropic layer may be measured by extracting the photopolymerizable liquid crystal compound from the optically anisotropic layer to obtain an extracted solution, and then quantifying the amount of the photopolymerizable liquid crystal compound in the extracted solution. The quantification of the photopolymerizable liquid crystal compound in the extracted solution may be performed by a quantification method such as high performance liquid chromatography (HPLC).

In the optically anisotropic layer having a higher residual monomer ratio, the dichroic ratios ε₁ₘ/ε₁ₛ and ε₂ₘ/ε₂ₛ of absorbances of the optically anisotropic layer can be set within the aforementioned ranges by a method including selecting the photopolymerizable liquid crystal compound, controlling the orientation of the photopolymerizable liquid crystal compound in the liquid crystal composition before curing, and the like. However, it is difficult to maintain the properties after a durability test. When the residual monomer ratio is decreased as described above, the dichroic ratios ε₁ₘ/ε₁ₛ and ε₂ₘ/ε₂ₛ of absorbances of the optically anisotropic layer after the durability test can be maintained within the aforementioned ranges. Therefore, favorable reverse wavelength distribution can be obtained not only before the durability test but also after the durability test.

The method for setting the residual monomer ratio of the optically anisotropic layer within the aforementioned range is not restricted. The photopolymerizable liquid crystal compound contained in the optically anisotropic layer is usually the residual monomer that is not polymerized during curing of the liquid crystal composition. Therefore, for example, the conditions during curing of the liquid crystal composition may be adjusted to thereby set the residual monomer ratio of the optically anisotropic layer within the aforementioned range. Specific examples of the method may include a method in which the amount of a polymerization initiator is adjusted, a method in which the type of the polymerization initiator is appropriately selected, a method in which the temperature in a step of curing the liquid crystal composition is adjusted, and a method in which the integrated light amount in a step of curing the liquid crystal composition is adjusted.

A specific in-plane retardation of the optically anisotropic layer may be set according to use application of the optically anisotropic layer. In particular, it is preferable that the optically anisotropic layer has an in-plane retardation capable of functioning as a λ/2 wave plate or a λ/4 wave plate. It is more preferable that the optically anisotropic layer has an in-plane retardation capable of functioning as a λ/4 wave plate. When the optically anisotropic layer functions as such a λ/4 wave plate or a λ/2 wave plate, an optical element such as a circularly polarizing plate having a λ/4 wave plate or a λ/2 wave plate can be easily produced by using the optically anisotropic layer.

Specifically, when the in-plane retardation Re(A550) measured at a measurement wavelength of 550 nm is 108 nm to 168 nm, the optically anisotropic layer can function as a λ/4 wave plate. When the in-plane retardation Re(A550) measured at a measurement wavelength of 550 nm is 245 nm to 305 nm, the optically anisotropic layer can function as a λ/2 wave plate. More specifically, in a case of λ/4 wave plate, the in-plane retardation Re(A550) measured at a measurement wavelength of 550 nm is preferably 108 nm or more, more preferably 110 nm or more, further preferably 128 nm or more, and particularly preferably 135 nm more, and is preferably 168 nm or less, more preferably 158 nm or less, further preferably 148 nm or less, and particularly preferably 145 nm or less. In a case of λ/2 wave plate, the in-plane retardation Re(A550) measured at a measurement wavelength of 550 nm is preferably 245 nm or more, more preferably 265 nm or more, and further preferably 270 nm or more, and is preferably 305 nm or less, more preferably 285 nm or less, and further preferably 280 nm or less.

The optically anisotropic layer usually has a slow axis parallel to the orientation direction of the optically anisotropic layer. The specific direction of a slow axis of the optically anisotropic layer may be optionally set according to use application of the optically anisotropic layer. When the optically anisotropic layer has a long-length shape, the angle formed between the slow axis of the optically anisotropic layer and the width direction of the optically anisotropic layer is preferably larger than 0° and less than 90°. In a certain aspect, the angle formed between the slow axis of the optically anisotropic layer and the width direction of the optically anisotropic layer may be set within a specific range of preferably 15°±5°, 22.5°±5°, 45°±5°, or 75°±5°, more preferably 15°±4°, 22.5°±4°, 45°±4°, or 75°±4°, and further preferably 15°±3°, 22.5°±3°, 45°±3°, or 75°±3°. When such an angle relationship is satisfied, the optically anisotropic layer can be used as a material capable of efficiently producing a circularly polarizing plate.

The thickness of the optically anisotropic layer is not particularly limited, and may be appropriately adjusted so that the properties such as in-plane retardation fall within desired ranges. Specifically, the thickness of the optically anisotropic layer is preferably 0.5 μm or more, and more preferably 1.0 μm or more, and is preferably 10 μm or less, more preferably 7 μm or less, and particularly preferably 5 μm or less.

It is preferable that the optically anisotropic layer has a long-length shape from the viewpoint of efficient production.

[2. Liquid Crystal Composition]

The liquid crystal composition that may be used in formation of the optically anisotropic layer will be described. The liquid crystal composition contains the photopolymerizable liquid crystal compound, and if necessary, an optional component.

A liquid crystal compound is a compound that is capable of exhibiting a liquid crystal phase when the liquid crystal compound is mixed in the liquid crystal composition and oriented. The photopolymerizable liquid crystal compound is a liquid crystal compound that is capable of being polymerized in the liquid crystal composition while the compound is in a state of exhibiting the liquid crystal phase, to form a polymer in which the orientation of molecules in the liquid crystal phase is maintained.

In the following description, compounds having polymerizability (photopolymerizable liquid crystal compound, other compounds having polymerizability, etc.) as the component of the liquid crystal composition may be collectively simply referred to as “polymerizable compound”.

The CN point of the photopolymerizable liquid crystal compound is preferably 25° C. or higher, more preferably 45° C. or higher, and particularly preferably 60° C. or higher, and is preferably 120° C. or lower, more preferably 110° C. or lower, and particularly preferably 100° C. or lower. Herein, “CN point” refers to a crystal-nematic phase transition temperature. When a photopolymerizable liquid crystal compound having a CN point within the aforementioned range is used, the optically anisotropic layer can be easily produced.

Examples of the photopolymerizable liquid crystal compound may include a liquid crystal compound having a polymerizable group, a compound capable of forming a side chain-type liquid crystal polymer, and a discotic liquid crystal compound. Among these, a photopolymerizable compound that is capable of being polymerized by irradiation with light such as visible light, ultraviolet light, and infrared light is preferable. Examples of the liquid crystal compound having a polymerizable group may include rod-like liquid crystal compounds having a polymerizing group described in Japanese Patent Application Laid-Open Nos. Hei. 11-513360 A, 2002-030042 A, 2004-204190 A, 2005-263789 A, 2007-119415 A, and 2007-186430 A. Examples of the side chain-type liquid crystal polymer compound may include a side chain-type liquid crystal polymer compound described in Japanese Patent Application Laid-Open No. 2003-177242 A. Examples of product name of preferable liquid crystal compound may include “LC242” available from BASF. Specific examples of the discotic liquid crystal compound are described in Japanese Patent Application Laid-Open No. Hei, 8-50206 A, and literatures (C. Destrade et al., Mol. Cryst. Liq. Cryst., vol. 71, page 111 (1981); Quarterly Chemical Review by the Chemical Society of Japan, No. 22, Chemistry of Liquid Crystals, Chapter 5, Section 2 of Chapter 10 (1994); and J. Zhang et al., J. Am. Chem. Soc., vol. 116, page 2655 (1994)). As the photopolymerizable liquid crystal compound, one type thereof may be solely used, and two or more types thereof may also be used in combination at any ratio.

In particular, the photopolymerizable liquid crystal compound is preferably a photopolymerizable liquid crystal compound with reverse wavelength distribution. Herein, the photopolymerizable liquid crystal compound with reverse wavelength distribution is a photopolymerizable liquid crystal compound a polymer obtained with which exhibits reverse wavelength distribution. When the photopolymerizable liquid crystal compound with reverse wavelength distribution is used as a part or the entirety of the photopolymerizable liquid crystal compound contained in the liquid crystal composition, the optically anisotropic layer having reverse wavelength distribution can be easily obtained.

As the photopolymerizable liquid crystal compound with reverse wavelength distribution, a compound having a main chain mesogen and a side chain mesogen bonded to the main chain mesogen in a molecule of the photopolymerizable liquid crystal compound with reverse wavelength distribution may be used. When the photopolymerizable liquid crystal compound with reverse wavelength distribution having the main chain mesogen and the side chain mesogen is in an oriented state, the side chain mesogen may be oriented in a direction different from that of the main chain mesogen. Therefore, the main chain mesogen and the side chain mesogen may be oriented in different directions in the polymer obtained by polymerization of the photopolymerizable liquid crystal compound with reverse wavelength distribution while such orientation is maintained. In this case, birefringence is exhibited as a difference between the refractive index corresponding to the main chain mesogen and the refractive index corresponding to the side chain mesogen. Therefore, the photopolymerizable liquid crystal compound with reverse wavelength distribution and the polymer thereof can exhibit reverse wavelength distribution.

The steric structure of the compound having the main chain mesogen and the side chain mesogen as described above is a specific structure that is different from that of a general photopolymerizable liquid crystal compound with normal wavelength distribution. Herein, the “photopolymerizable liquid crystal compound with normal wavelength distribution” is a photopolymerizable liquid crystal compound a polymer obtained with which exhibits normal wavelength distribution. The normal wavelength distribution refers to properties in which the in-plane retardation Re(450) at a wavelength of 450 nm, the in-plane retardation Re(550) at a wavelength of 550 nm, and the in-plane retardation Re(650) at a wavelength of 650 nm satisfy the following expressions (9) and (10):

Re(450)/Re(550)>1.00 (9), and

Re(650)/Re(550)<1.00 (10).

Examples of the polymerizable liquid crystal compound with reverse wavelength distribution may include a compound represented by the following formula (Ia). In the following description, the compound represented by the formula (Ia) may be appropriately referred to as “compound (Ia)”.

Z^{1a}—Y^{7a}-G^{1a}-Y^{5a}-A^{4a}-Y^{3a}A^{2a}-Y^{1a})ₖ-A^{1a}Y^{2a}-A^{3a})ₗ-Y^{4a}-A^{5a}-Y^{6a}-G^{2a}-Y^{8a}—Z^{2a} (Ia)

In the formula (Ia), Y^{1a} to Y^{8a}, G^{1a}, G^{2a}, Z^{1a}, Z^{2a}, and A^{2a} to A^{5a} each independently have the same meaning as Y¹ to Y⁸, G¹, G², Z¹, Z², and A² to A⁵ described later, and suitable examples thereof are the same as those of Y¹ to Y⁸, G¹, G², Z¹, Z², and A² to A⁵.

In the formula (Ia), A^{1a} is an aromatic hydrocarbon ring group having as a substituent an organic group of 1 to 67 carbon atoms having at least one aromatic ring selected from the group consisting of an aromatic hydrocarbon ring and an aromatic heterocyclic ring; or an aromatic heterocyclic group having as a substituent an organic group of 1 to 67 carbon atoms having at least one aromatic ring selected from the group consisting of an aromatic hydrocarbon ring and an aromatic heterocyclic ring.

Specific examples of A^{1a} may include an aromatic group substituted with a group represented by —C(R^{f})═N—N(R^{g}) R^{h} or —C(R^{f})═N—N═C(R^{f1})R^{h}; a benzothiazol-4,7-diyl group substituted with a 1-benzofuran-2-yl group; a benzothiazol-4,7-diyl group substituted with a 5-(2-butyl)-1-benzofuran-2-yl group; a benzothiazol-4,7-diyl group substituted with a 4,6-dimethyl-1-benzofuran-2-yl group; a benzothiazol-4,7-diyl group substituted with a 6-methyl-1-benzofuran-2-yl group; a benzothiazol-4,7-diyl group substituted with a 4,6,7-trimethyl-1-benzofuran-2-yl group; a benzothiazol-4,7-diyl group substituted with a 4,5,6-trimethyl-1-benzofuran-2-yl group; a benzothiazol-4,7-diyl group substituted with a 5-methyl-1-benzofuran-2-yl group; a benzothiazol-4,7-diyl group substituted with a 5-propyl-1-benzofuran-2-yl group; a benzothiazol-4,7-diyl group substituted with a 7-propyl-1-benzofuran-2-yl group; a benzothiazol-4,7-diyl group substituted with a 5-fluoro-1-benzofuran-2-yl group; a benzothiazol-4,7-diyl group substituted with a phenyl group; a benzothiazol-4,7-diyl group substituted with a 4-fluorophenyl group; a benzothiazol-4,7-diyl group substituted with a 4-nitrophenyl group; a benzothiazol-4,7-diyl group substituted with a 4-trifluoromethylphenyl group; a benzothiazol-4,7-diyl group substituted with a 4-cyanophenyl group; a benzothiazol-4,7-diyl group substituted with a 4-methanesufonylphenyl group; a benzothiazol-4,7-diyl group substituted with a thiophen-2-yl group; a benzothiazol-4,7-diyl group substituted with a thiophen-3-yl group; a benzothiazol-4,7-diyl group substituted with a 5-methylthiophen-2-yl group; a benzothiazol-4,7-diyl group substituted with a 5-chlorothiophen-2-yl group; a benzothiazol-4,7-diyl group substituted with a thieno[3,2-b]thiophen-2-yl group; a benzothiazol-4,7-diyl group substituted with a 2-benzothiazolyl group; a benzothiazol-4,7-diyl group substituted with a 4-biphenyl group; a benzothiazol-4,7-diyl group substituted with a 4-propylbiphenyl group; a benzothiazol-4,7-diyl group substituted with a 4-thiazolyl group; a benzothiazol-4,7-diyl group substituted with a 1-phenylethylen-2-yl group; a benzothiazol-4,7-diyl group substituted with a 4-pyridyl group; a benzothiazol-4,7-diyl group substituted with a 2-furyl group; a benzothiazol-4,7-diyl group substituted with a naphtho[1,2-b]furan-2-yl group; a 1H-isoindole-1,3(2H)-dion-4,7-diyl group substituted with a 5-methoxy-2-benzothiazolyl group; a 1H-isoindole-1,3(2H)-dion-4,7-diyl group substituted with a phenyl group; a 1H-isoindole-1,3(2H)-dion-4,7-diyl group substituted with a 4-nitrophenyl group; and a 1H-isoindole-1,3(2H)-dion-4,7-diyl group substituted with a 2-thiazolyl group. Herein, R^{f} and R^{f1} each independently have the same meaning as Q¹ described later. R^{g} has the same meaning as A^{y} described later, and R^{h} has the same meaning as A^{x} described later.

In the formula (Ia), k and l are each independently 0 or 1.

Specific preferable examples of the photopolymerizable liquid crystal compound with reverse wavelength distribution may include a compound represented by the following formula (I). Hereinafter, the compound represented by the formula (I) may be appropriately referred to as “compound (I)”.

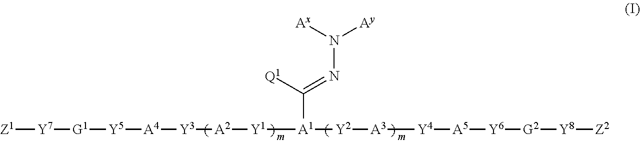

When the photopolymerizable liquid crystal compound with reverse wavelength distribution is the compound (I), a —Y⁵-A⁴-Y³-A²-Y¹-A¹-Y²-A³-Y⁴-A⁵-Y⁶— group is the main chain mesogen, and a group represented by the following formula (A) is the side chain mesogen. In the formula (A), A^{x}, A^{y}, A¹, and Q¹ have the same meaning as A^{x}, A^{y}, A¹, and Q¹ in the formula (I). The A1 group affects nature of both the main chain mesogen and the side chain mesogen. Since the side chain mesogen represented by the formula (A) is contained, a polymerizable liquid crystal compound with reverse wavelength distribution having all of reverse wavelength distribution, solubility in an organic solvent, and a low melting point that enables application onto a film is obtained.

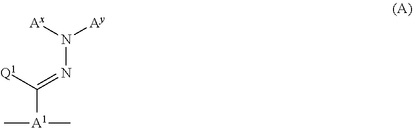

In the formula (I) mentioned above, Y¹ to Y⁸ are each independently a chemical single bond, —O—, —S—, —O—C(═O)—, —C(═O)—O—, —O—C(═O)—O—, —NR¹—C(═O)—, —C(═O)—NR¹—, —O—C(═O)—NR¹—, —NR¹—C(═O)—O—, —NR¹—C(═O)—NR¹—, —O—NR¹—, or —NR¹—O—.

Herein, R¹ is a hydrogen atom or an alkyl group of 1 to 6 carbon atoms.

Examples of the alkyl group of 1 to 6 carbon atoms of R¹ may include a methyl group, an ethyl group, a n-propyl group, an isopropyl group, a n-butyl group, a sec-butyl group, a t-butyl group, a n-pentyl group, and a n-hexyl group.

It is preferable that R¹ is a hydrogen atom or an alkyl group of 1 to 4 carbon atoms.

In the compound (I), it is preferable that Y¹ to Y⁸ are each independently a chemical single bond, —O—, —O—C(═O)—, —C(═O)—O—, or —O—C(═O)—O—.

In the formula (I) mentioned above, G¹ and G² are each independently a divalent aliphatic group of 1 to 20 carbon atoms optionally having a substituent.

Examples of the divalent aliphatic group of 1 to 20 carbon atoms may include a divalent aliphatic group having a linear structure, such as an alkylene group of 1 to 20 carbon atoms and an alkenylene group of 2 to 20 carbon atoms; and a divalent aliphatic group, such as a cycloalkanediyl group of 3 to 20 carbon atoms, a cycloalkenediyl group of 4 to 20 carbon atoms, and a divalent alicyclic fused ring group of 10 to 30 carbon atoms.

Examples of the substituent in the divalent aliphatic group of G¹ and G² may include a halogen atom, such as a fluorine atom, a chlorine atom, a bromine atom, and an iodine atom; and an alkoxy group of 1 to 6 carbon atoms, such as a methoxy group, an ethoxy group, a n-propoxy group, an isopropoxy group, a n-butoxy group, a sec-butoxy group, a t-butoxy group, a n-pentyloxy group, and a n-hexyloxy group. Among these, a fluorine atom, a methoxy group, and an ethoxy group are preferable.

The aforementioned aliphatic groups may have one or more per one aliphatic group of —O—, —S—, —O—C(═O)—, —C(═O)—O—, —O—C(═O)—O—, —NR²—C(═O)—, —C(═O)—NR²—, —NR²—, or —C(═O)— inserted therein. However, cases where two or more —O— or —S— are each adjacently inserted are excluded. Herein, R² is a hydrogen atom or an alkyl group of 1 to 6 carbon atoms, in the same manner as the aforementioned R¹. It is preferable that R² is a hydrogen atom or a methyl group.

It is preferable that the group inserted into the aliphatic groups is —O—, —O—C(═O)—, —C(═O)—O—, or —C(═O)—.

Specific examples of the aliphatic groups into which the group is inserted may include —CH₂—CH₂—O—CH₂—CH₂—, —CH₂—CH₂—S—CH₂—CH₂—, —CH₂—CH₂—O—C(═O)—CH₂—CH₂—, —CH₂—CH₂—C(═O)—O—CH₂—CH₂—, —CH₂—CH₂—C(═O)—O—CH₂—, —CH₂—O—C(═O)—O—CH₂—CH₂—, —CH₂—CH₂—NR²—C(═O)—CH₂—CH₂—, —CH₂—CH₂—C(═O)—NR²—CH₂—, —CH₂—NR²—CH₂—CH₂—, and —CH₂—C(═O)—CH₂—.

Among these, from the viewpoint of more favorably expressing the desired effect of the present invention, G¹ and G² are each independently preferably a divalent aliphatic group having a linear structure, such as an alkylene group of 1 to 20 carbon atoms and an alkenylene group of 2 to 20 carbon atoms, more preferably an alkylene group of 1 to 12 carbon atoms, such as a methylene group, an ethylene group, a trimethylene group, a propylene group, a tetramethylene group, a pentamethylene group, a hexamethylene group, an octamethylene group, and a decamethylene group [—(CH₂)₁₀—], and particularly preferably a tetramethylene group [—(CH₂)₄—], a hexamethylene group [—(CH₂)₆—], an octamethylene group [—(CH₂)₈—], or a decamethylene group [—(CH₂)₁₀—].

In the formula (I) mentioned above, Z¹ and Z² are each independently an alkenyl group of 2 to 10 carbon atoms that are non-substituted or substituted by a halogen atom.

It is preferable that the number of carbon atoms in the alkenyl group is 2 to 6. Examples of the halogen atom that is a substituent in the alkenyl group of Z¹ and Z² may include a fluorine atom, a chlorine atom, and a bromine atom. A chlorine atom is preferable.

Specific examples of the alkenyl group of 2 to 10 carbon atoms of Z¹ and Z² may include CH₂═CH—, CH₂═C(CH₃)—, CH₂═CH—CH₂—, CH₃—CH═CH—, CH₂═CH—CH₂—CH₂—, CH₂═C(CH₃)—CH₂—CH₂—, (CH₃)₂C—CH—CH₂—, (CH₃)₂C—CH—CH₂—CH₂—, CH₂—C(Cl)—, CH₂—C(CH₃)—CH₂—, and CH₃—CH═CH—CH₂—.

Among these, from the viewpoint of favorably expressing the desired effect of the present invention, Z¹ and Z² are each independently preferably CH₂═CH—, CH₂═C(CH₃)—, CH₂═C(Cl)—, CH₂═CH—CH₂—, CH₂═C(CH₃)—CH₂—, or CH₂═C(CH₃)—CH₂—CH₂—, more preferably CH₂═CH—, CH₂═C(CH₃)— or CH₂═C(Cl)—, and particularly preferably CH₂═CH—.

In the formula (I) mentioned above, A^{x} is an organic group of 2 to 30 carbon atoms having at least one aromatic ring selected from the group consisting of an aromatic hydrocarbon ring and an aromatic heterocyclic ring. The “aromatic ring” means a cyclic structure having aromaticity in the broad sense based on Huckel rule, that is, a cyclic conjugated structure having (4n+2) π electrons, and a cyclic structure that exhibits aromaticity by involving a lone pair of electrons of a heteroatom, such as sulfur, oxygen, and nitrogen, in a π electron system, typified by thiophene, furan, and benzothiazole.

The organic group of 2 to 30 carbon atoms having at least one aromatic ring selected from the group consisting of an aromatic hydrocarbon ring and an aromatic heterocyclic ring, of A^{x}, may have a plurality of aromatic rings, or have an aromatic hydrocarbon ring and an aromatic heterocyclic ring.

Examples of the aromatic hydrocarbon ring may include a benzene ring, a naphthalene ring, and an anthracene ring. Examples of the aromatic heterocyclic ring may include a monocyclic aromatic heterocyclic ring, such as a pyrrole ring, a furan ring, a thiophene ring, a pyridine ring, a pyridazine ring, a pyrimidine ring, a pyrazine ring, a pyrazole ring, an imidazole ring, an oxazole ring, and a thiazole ring; and a fused aromatic heterocyclic ring, such as a benzothiazole ring, a benzoxazole ring, a quinoline ring, a phthalazine ring, a benzimidazole ring, a benzopyrazole ring, a benzofuran ring, a benzothiophene ring, a thiazolopyridine ring, an oxazolopyridine ring, a thiazolopyrazine ring, an oxazolopyrazine ring, a thiazolopyridazine ring, an oxazolopyridazine ring, a thiazolopyrimidine ring, and an oxazolopyrimidine ring.

The aromatic ring of A^{x} may have a substituent. Examples of the substituent may include a halogen atom, such as a fluorine atom and a chlorine atom; a cyano group; an alkyl group of 1 to 6 carbon atoms, such as a methyl group, an ethyl group, and a propyl group; an alkenyl group of 2 to 6 carbon atoms, such as a vinyl group and an allyl group; a halogenated alkyl group of 1 to 6 carbon atoms, such as a trifluoromethyl group; a substituted amino group, such as a dimethylamino group; an alkoxy group of 1 to 6 carbon atoms, such as a methoxy group, an ethoxy group, and an isopropoxy group; a nitro group; an aryl group, such as a phenyl group and a naphthyl group; —C(═O)—R⁵; —C(═O)—OR⁵; and —SO₂R⁶. Herein, R⁵ is an alkyl group of 1 to 20 carbon atoms, an alkenyl group of 2 to 20 carbon atoms, or a cycloalkyl group of 3 to 12 carbon atoms. R⁶ is an alkyl group of 1 to 20 carbon atoms, an alkenyl group of 2 to 20 carbon atoms, a phenyl group, or a 4-methylphenyl group, which are the same as those for R⁴ which will be described later.

The aromatic ring of A^{x} may have a plurality of substituents that may be the same or different, and two adjacent substituents may be bonded together to form a ring. The formed ring may be a monocycle or a fused polycycle, and may be an unsaturated ring or a saturated ring.

The “number of carbon atoms” in the organic group of 2 to 30 carbon atoms of A^{x} means the total number of carbon atoms in the entire organic group which excludes carbon atoms in the substituents (the same applies to A^{y} which will be described later).

Examples of an organic group of 2 to 30 carbon atoms having at least one aromatic ring selected from the group consisting of an aromatic hydrocarbon ring and an aromatic heterocyclic ring of A^{x} may include an aromatic hydrocarbon ring group such as a benzene ring group, a naphthalene ring group, and an anthracene ring group; an aromatic heterocyclic group such as a pyrrole ring group, a furan ring group, a thiophene ring group, a pyridine ring group, a pyridazine ring group, a pyrimidine ring group, a pyrazine ring group, a pyrazole ring group, an imidazole ring group, an oxazole ring group, a thiazole ring group, a benzothiazole ring group, a benzoxazole ring group, a quinoline ring group, a phthalazine ring group, a benzimidazole ring group, a benzopyrazole ring group, a benzofuran ring group, a benzothiophene ring group, a thiazolopyridine ring group, an oxazolopyridine ring group, a thiazolopyrazine ring group, an oxazolopyrazine ring group, a thiazolopyridazine ring group, an oxazolopyridazine ring group, a thiazolopyrimidine ring group, and an oxazolopyrimidine ring group; a heterocyclic group having at least one aromatic ring; an alkyl group of 3 to 30 carbon atoms having at least one aromatic ring selected from the group consisting of an aromatic hydrocarbon ring and an aromatic heterocyclic ring; an alkenyl group of 4 to 30 carbon atoms having at least one aromatic ring selected from the group consisting of an aromatic hydrocarbon ring and an aromatic heterocyclic ring; and an alkynyl group of 4 to 30 carbon atoms having at least one aromatic ring selected from the group consisting of an aromatic hydrocarbon ring and an aromatic heterocyclic ring.

The organic group may have a substituent. Examples of the substituent may include a halogen atom such as a fluorine atom and a chlorine atom; a cyano group; an alkyl group of 1 to 6 carbon atoms such as a methyl group, an ethyl group, and a propyl group; an alkenyl group of 2 to 6 carbon atoms such as a vinyl group and an allyl group; a halogenated alkyl group of 1 to 6 carbon atoms such as a trifluoromethyl group; a substituted amino group such as a dimethylamino group; an alkoxy group of 1 to 6 carbon atoms such as a methoxy group, an ethoxy group, and an isopropoxy group; a nitro group; an aryl group such as a phenyl group and a naphthyl group; —C(═O)—R⁸; —C(═O)—OR⁸; and —SO₂R⁶. Herein, R⁸ is an alkyl group of 1 to 6 carbon atoms such as a methyl group and an ethyl group; or an aryl group of 6 to 14 carbon atoms such as a phenyl group. Among these, a halogen atom, a cyano group, an alkyl group of 1 to 6 carbon atoms, and an alkoxy group of 1 to 6 carbon atoms are preferable.

Specific preferable examples of A^{x} are as follows. However, A^{x} is not limited to the following examples. In the following formulae, “-” represents an atomic bond extended from any position of the ring to an N atom (that is, in the formula (I) or (A), an N atom bonded to A^{x}) (the same applies to the following).

(1) An aromatic hydrocarbon ring group

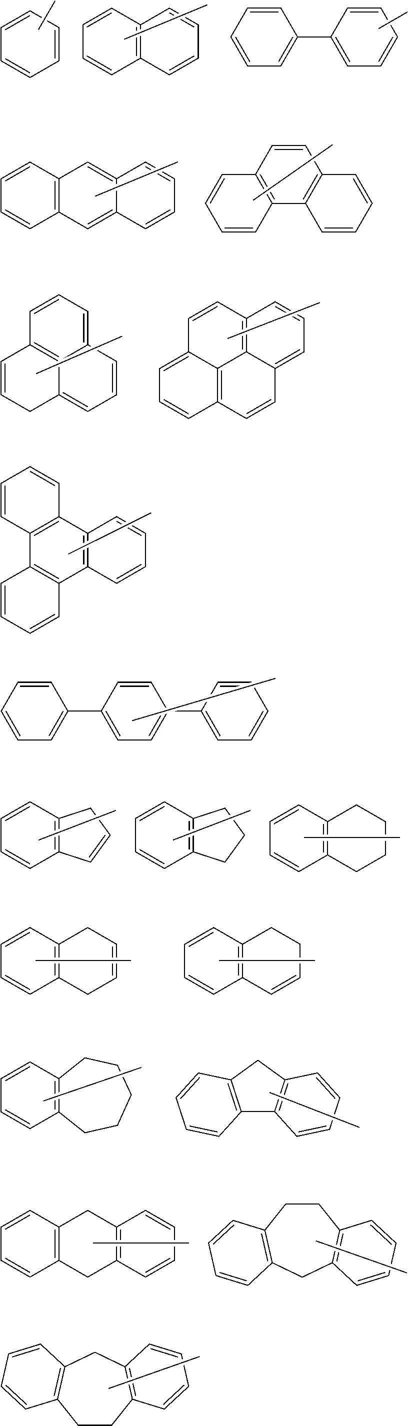

(2) An aromatic heterocyclic ring group

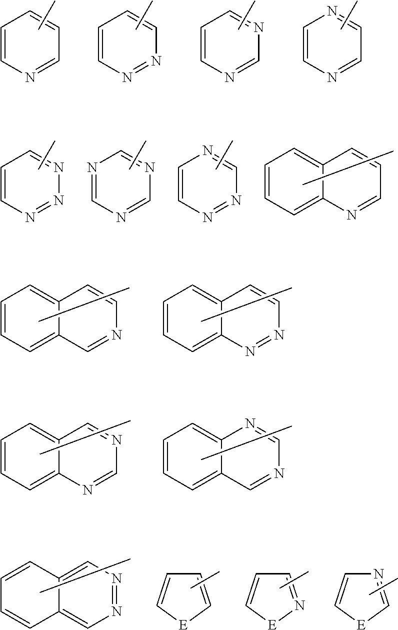

In the formulae described above, E is NR^{6a}, an oxygen atom, or a sulfur atom. Herein, R^{6a} is a hydrogen atom; or an alkyl group of 1 to 6 carbon atoms such as a methyl group, an ethyl group, and a propyl group.

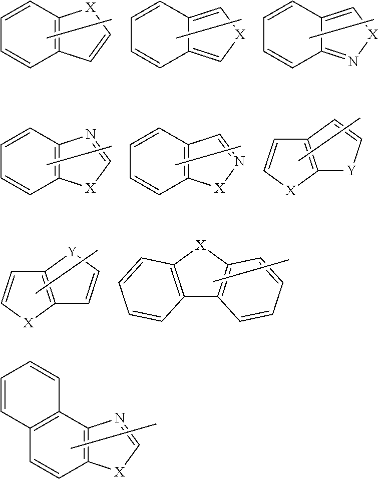

In the formulae described above, X and Y are each independently NR⁷, an oxygen atom, a sulfur atom, —SO—, or —SO₂— (provided that a case where an oxygen atom, a sulfur atom, —SO—, and —SO₂— are each adjacent is excluded). R⁷ is a hydrogen atom; or an alkyl group of 1 to 6 carbon atoms such as a methyl group, an ethyl group, and a propyl group, that are the same as those for R^{6a} described above.

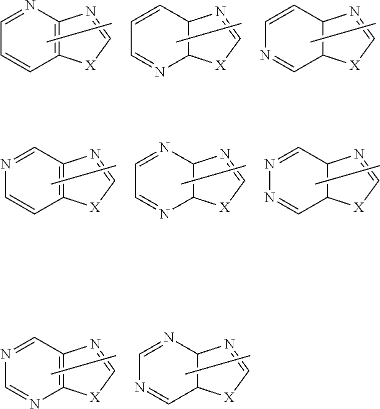

(In the formulae described above, X has the same meaning as described above.)

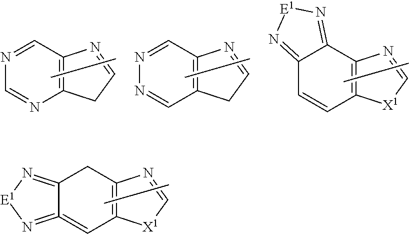

[In each of the formulae, X¹ is —CH₂—, NR^{c}—, an oxygen atom, a sulfur atom, —SO, or —SO₂—, and E¹ is —NR^{c}—, an oxygen atom, or a sulfur atom. Herein, R^{c} is a hydrogen atom; or an alkyl group of 1 to 6 carbon atoms such as a methyl group, an ethyl group, and a propyl group. (Provided that an oxygen atom, a sulfur atom, —SO—, and —SO₂— are not adjacent to each other in each of the formulae.)]

(3) A heterocyclic group having at least one aromatic ring

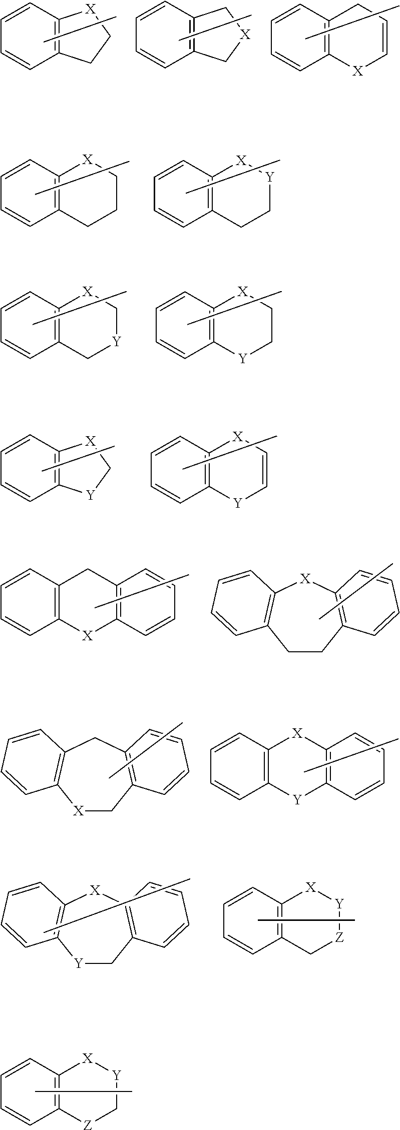

(In the formulae, X and Y each independently have the same meaning as described above. In the formulae, Z is NR⁷, an oxygen atom, a sulfur atom, —SO—, or —SO₂-(provided that a case where an oxygen atom, a sulfur atom, —SO—, and —SO₂— are each adjacent is excluded.).)

(4) An alkyl group having at least one aromatic ring selected from the group consisting of an aromatic hydrocarbon ring and an aromatic heterocyclic ring

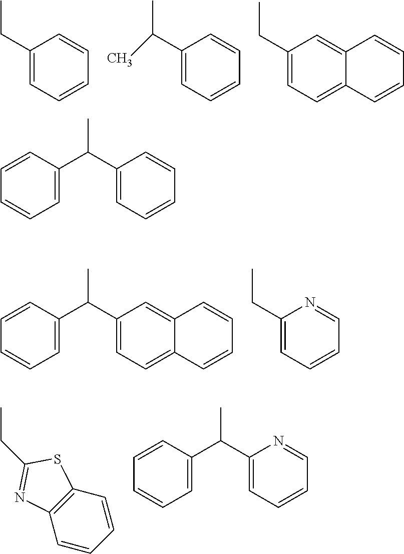

(5) An alkenyl group having at least one aromatic ring selected from the group consisting of an aromatic hydrocarbon ring and an aromatic heterocyclic ring

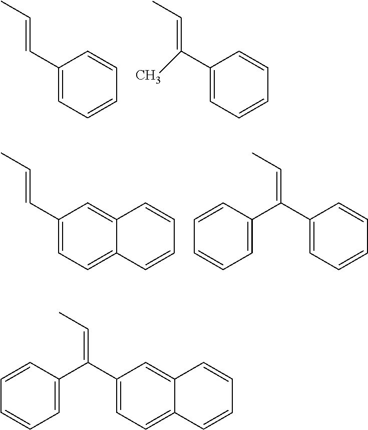

(6) An alkynyl group having at least one aromatic ring selected from the group consisting of an aromatic hydrocarbon ring and an aromatic heterocyclic ring

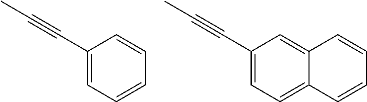

Of A^{x} described above, an aromatic hydrocarbon ring group of 6 to 30 carbon atoms and an aromatic heterocyclic group of 4 to 30 carbon atoms are preferable, and any groups described below are more preferable.

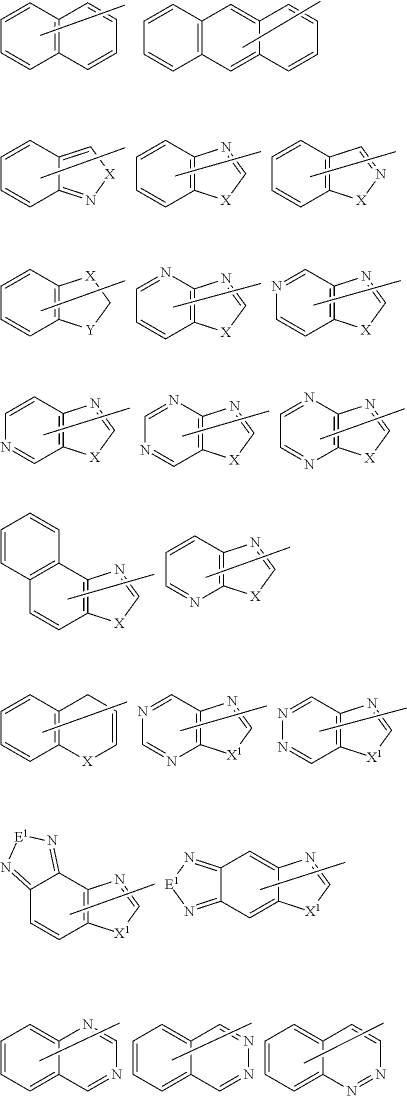

(In the formulae, X, X¹, and E¹ have the same meaning as described above.)

Further, A^{x} is preferably any of the groups described below.

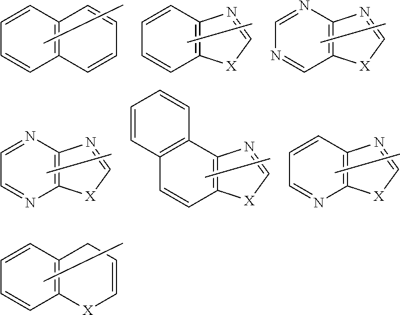

(In the formulae, X has the same meaning as described above.)

The ring that A^{x} has may have a substituent. Examples of the substituent may include a halogen atom, such as a fluorine atom and a chlorine atom; a cyano group; an alkyl group of 1 to 6 carbon atoms, such as a methyl group, an ethyl group, and a propyl group; an alkenyl group of 2 to 6 carbon atoms, such as a vinyl group and an allyl group; a halogenated alkyl group of 1 to 6 carbon atoms, such as a trifluoromethyl group; a substituted amino group, such as a dimethylamino group; an alkoxy group of 1 to 6 carbon atoms, such as a methoxy group, an ethoxy group, and an isopropoxy group; a nitro group; an aryl group, such as a phenyl group and a naphthyl group; —C(═O)—R⁸; —C(═O)—OR⁸; and —SO₂R⁸. Among these, a halogen atom, a cyano group, an alkyl group of 1 to 6 carbon atoms, and an alkoxy group of 1 to 6 carbon atoms.

The ring that A^{x} has may have a plurality of substituents that may be the same or different, and two adjacent substituents may be bonded together to form a ring. The formed ring may be a monocycle or a fused polycycle.

The “number of carbon atoms” in the organic group of 2 to 30 carbon atoms of A^{x} means the total number of carbon atoms in the entire organic group which excludes carbon atoms in the substituents (the same applies to A^{y} which will be described later).

In the aforementioned formula (I), A^{y} is a hydrogen atom, an alkyl group of 1 to 20 carbon atoms optionally having a substituent, an alkenyl group of 2 to 20 carbon atoms optionally having a substituent, a cycloalkyl group of 3 to 12 carbon atoms optionally having a substituent, an alkynyl group of 2 to 20 carbon atoms optionally having a substituent, —C(═O)—R³, —SO₂—R⁴, —C(═S)NH—R⁹, or an organic group of 2 to 30 carbon atoms having at least one aromatic ring selected from the group consisting of an aromatic hydrocarbon ring and an aromatic heterocyclic ring. Herein, R³ is an alkyl group of 1 to 20 carbon atoms optionally having a substituent, an alkenyl group of 2 to 20 carbon atoms optionally having a substituent, a cycloalkyl group of 3 to 12 carbon atoms optionally having a substituent, or an aromatic hydrocarbon ring group of 5 to 12 carbon atoms. R⁴ is an alkyl group of 1 to 20 carbon atoms, an alkenyl group of 2 to 20 carbon atoms, a phenyl group, or a 4-methylphenyl group. R⁹ is an alkyl group of 1 to 20 carbon atoms optionally having a substituent, an alkenyl group of 2 to 20 carbon atoms optionally having a substituent, a cycloalkyl group of 3 to 12 carbon atoms optionally having a substituent, or an aromatic group of 5 to 20 carbon atoms optionally having a substituent.

Examples of the alkyl group of 1 to 20 carbon atoms in the alkyl group of 1 to 20 carbon atoms optionally having a substituent, of A^{y}, may include a methyl group, an ethyl group, a n-propyl group, an isopropyl group, a n-butyl group, an isobutyl group, a 1-methylpentyl group, a 1-ethylpentyl group, a sec-butyl group, a t-butyl group, a n-pentyl group, an isopentyl group, a neopentyl group, a n-hexyl group, an isohexyl group, a n-heptyl group, a n-octyl group, a n-nonyl group, a n-decyl group, a n-undecyl group, a n-dodecyl group, a n-tridecyl group, a n-tetradecyl group, a n-pentadecyl group, a n-hexadecyl group, a n-heptadecyl group, a n-octadecyl group, a n-nonadecyl group, and a n-icosyl group. The number of carbon atoms in the alkyl group of 1 to 20 carbon atoms optionally having a substituent is preferably 1 to 12, and further preferably 4 to 10.

Examples of the alkenyl group of 2 to 20 carbon atoms in the alkenyl group of 2 to 20 carbon atoms optionally having a substituent, of A^{y}, may include a vinyl group, a propenyl group, an isopropenyl group, a butenyl group, an isobutenyl group, a pentenyl group, a hexenyl group, a heptenyl group, an octenyl group, a decenyl group, an undecenyl group, a dodecenyl group, a tridecenyl group, a tetradecenyl group, a pentadecenyl group, a hexadecenyl group, a heptadecenyl group, an octadecenyl group, a nonadecenyl group, and an icocenyl group. The number of carbon atoms in the alkenyl group of 2 to 20 carbon atoms optionally having a substituent is preferably 2 to 12.

Examples of the cycloalkyl group of 3 to 12 carbon atoms in the cycloalkyl group of 3 to 12 carbon atoms optionally having a substituent, of A^{y}, may include a cyclopropyl group, a cyclobutyl group, a cyclopentyl group, a cyclohexyl group, and a cyclooctyl group.

Examples of the alkynyl group of 2 to 20 carbon atoms in the alkynyl group of 2 to 20 carbon atoms optionally having a substituent, of A^{y}, may include an ethynyl group, a propynyl group, a 2-propynyl group (propargyl group), a butynyl group, a 2-butynyl group, a 3-butynyl group, a pentynyl group, a 2-pentynyl group, a hexynyl group, a 5-hexynyl group, a heptynyl group, an octynyl group, a 2-octynyl group, a nonanyl group, a decanyl group, and a 7-decanyl group.

Examples of the substituents in the alkyl group of 1 to 20 carbon atoms optionally having a substituent and the alkenyl group of 2 to 20 carbon atoms optionally having a substituent, of A^{y}, may include a halogen atom, such as a fluorine atom and a chlorine atom; a cyano group; a substituted amino group, such as a dimethylamino group; an alkoxy group of 1 to 20 carbon atoms, such as a methoxy group, an ethoxy group, an isopropyl group, and a butoxy group; an alkoxy group of 1 to 12 carbon atoms that is substituted by an alkoxy group of 1 to 12 carbon atoms, such as a methoxymethoxy group and a methoxyethoxy group; a nitro group; an aryl group, such as a phenyl group and a naphthyl group; a cycloalkyl group of 3 to 8 carbon atoms, such as a cyclopropyl group, a cyclopentyl group, and a cyclohexyl group; a cycloalkyloxy group of 3 to 8 carbon atoms, such as a cyclopentyloxy group, and a cyclohexyloxy group; a cyclic ether group of 2 to 12 carbon atoms, such as a tetrahydrofuranyl group, a tetrahydropyranyl group, a dioxolanyl group, and a dioxanyl group; an aryloxy group of 6 to 14 carbon atoms, such as a phenoxy group, and a naphthoxy group; a fluoroalkoxy group of 1 to 12 carbon atoms in which at least one is substituted by a fluoro atom, such as a trifluoromethyl group, a pentafluoroethyl group, and —CH₂CF₃; a benzofuryl group; a benzopyranyl group; a benzodioxolyl group; a benzodioxanyl group; —C(═O)—R^{7a}; —C(═O)—OR^{7a}; —SO₂R^{8a}; —SR¹⁰; an alkoxy group of 1 to 12 carbon atoms substituted by —SR¹⁰; and a hydroxyl group. Herein, R^{7a} and R¹⁰ are each independently an alkyl group of 1 to 20 carbon atoms, an alkenyl group of 2 to 20 carbon atoms, a cycloalkyl group of 3 to 12 carbon atoms, or an aromatic hydrocarbon ring group of 6 to 12 carbon atoms. R^{8a} is an alkyl group of 1 to 20 carbon atoms, an alkenyl group of 2 to 20 carbon atoms, a phenyl group, or a 4-methylphenyl group, which are the same as those for R⁴ described above.

Examples of the substituent in the cycloalkyl group of 3 to 12 carbon atoms optionally having a substituent, of A^{y}, may include a halogen atom, such as a fluorine atom and a chlorine atom; a cyano group; a substituted amino group, such as a dimethylamino group; an alkyl group of 1 to 6 carbon atoms, such as a methyl group, an ethyl group, and a propyl group; an alkoxy group of 1 to 6 carbon atoms, such as a methoxy group, an ethoxy group, and an isopropoxy group; a nitro group; an aryl group, such as a phenyl group and a naphthyl group; a cycloalkyl group of 3 to 8 carbon atoms, such as a cyclopropyl group, a cyclopentyl group, and a cyclohexyl group; —C(═O)—R^{7a}; —C(═O)—OR⁷a; —SO₂R^{8a}; and a hydroxyl group. Herein, R^{7a} and R^{8a} have the same meanings as described above.

Examples of the substituent in the alkynyl group of 2 to 20 carbon atoms optionally having a substituent, of A^{y}, may include substituents that are the same as the substituents in the alkyl group of 1 to 20 carbon atoms optionally having a substituent and the alkenyl group of 2 to 20 carbon atoms optionally having a substituent.

In the group represented by —C(═O)—R³ of A^{y}, R³ is an alkyl group of 1 to 20 carbon atoms optionally having a substituent, an alkenyl group of 2 to 20 carbon atoms optionally having a substituent, a cycloalkyl group of 3 to 12 carbon atoms optionally having a substituent, or an aromatic hydrocarbon ring group of 5 to 12 carbon atoms. Specific examples thereof may include those exemplified as the examples of the alkyl group of 1 to 20 carbon atoms optionally having a substituent, the alkenyl group of 2 to 20 carbon atoms optionally having a substituent, and the cycloalkyl group of 3 to 12 carbon atoms optionally having a substituent, of A^{y}; and the aromatic hydrocarbon ring group of 5 to 12 carbon atoms, among the aromatic hydrocarbon ring groups described in A^{x} described above.

In the group represented by —SO₂—R⁴ of A^{y}, R⁴ is an alkyl group of 1 to 20 carbon atoms, an alkenyl group of 2 to 20 carbon atoms, a phenyl group, or a 4-methylphenyl group. Specific examples of the alkyl group of 1 to 20 carbon atoms and the alkenyl group of 2 to 20 carbon atoms, of R⁴, may include those exemplified as the examples of the alkyl group of 1 to 20 carbon atoms, and the alkenyl group of 2 to 20 carbon atoms, of A^{y} described above.

Examples of the organic group of 2 to 30 carbon atoms having at least one aromatic ring selected from the group consisting of an aromatic hydrocarbon ring and an aromatic heterocyclic ring of A^{y} may include those exemplified as the examples of A^{x} described above.

Among these, A^{y} is preferably a hydrogen atom, an alkyl group of 1 to 20 carbon atoms optionally having a substituent, an alkenyl group of 2 to 20 carbon atoms optionally having a substituent, a cycloalkyl group of 3 to 12 carbon atoms optionally having a substituent, an alkynyl group of 2 to 20 carbon atoms optionally having a substituent, —C(═O)—R³, —SO₂—R⁴, or an organic group of 2 to 30 carbon atoms having at least one aromatic ring selected from the group consisting of an aromatic hydrocarbon ring and an aromatic heterocyclic ring, and further preferably a hydrogen atom, an alkyl group of 1 to 20 carbon atoms optionally having a substituent, an alkenyl group of 2 to 20 carbon atoms optionally having a substituent, a cycloalkyl group of 3 to 12 carbon atoms optionally having a substituent, an alkynyl group of 2 to 20 carbon atoms optionally having a substituent, an aromatic hydrocarbon ring group of 6 to 12 carbon atoms optionally having a substituent, an aromatic heterocyclic group of 3 to 9 carbon atoms optionally having a substituent, —C(═O)—R³, or a group represented by —SO₂—R⁴. Herein, R³ and R⁴ have the same meanings as described above.

It is preferable that substituents in the alkyl group of 1 to 20 carbon atoms optionally having a substituent, the alkenyl group of 2 to 20 carbon atoms optionally having a substituent, and the alkynyl group of 2 to 20 carbon atoms optionally having a substituent, of A^{y}, are a halogen atom, a cyano group, an alkoxy group of 1 to 20 carbon atoms, an alkoxy group of 1 to 12 carbon atoms that is substituted by an alkoxy group of 1 to 12 carbon atoms, a phenyl group, a cyclohexyl group, a cyclic ether group of 2 to 12 carbon atoms, an aryloxy group of 6 to 14 carbon atoms, a hydroxyl group, a benzodioxanyl group, a phenylsulfonyl group, a 4-methylphenylsulfonyl group, a benzoyl group, or —SR¹⁰. Herein, R¹⁰ has the same meanings as described above.

It is preferable that substituents in the cycloalkyl group of 3 to 12 carbon atoms optionally having a substituent, the aromatic hydrocarbon ring group of 6 to 12 carbon atoms optionally having a substituent, and the aromatic heterocyclic group of 3 to 9 carbon atoms optionally having a substituent, of A^{y}, are a fluorine atom, an alkyl group of 1 to 6 carbon atoms, an alkoxy group of 1 to 6 carbon atoms, or a cyano group.

Among the aforementioned ones, as A^{y}, a hydrogen atom, a n-hexyl group and 2-(1-cyano)-propyl group are preferable.

A^{x} and A^{y} may form a ring together. Examples of the ring may include an unsaturated heterocyclic ring of 4 to 30 carbon atoms optionally having a substituent and an unsaturated carbon ring of 6 to 30 carbon atoms optionally having a substituent.

The aforementioned unsaturated heterocyclic ring of 4 to 30 carbon atoms and the aforementioned unsaturated carbon ring of 6 to 30 carbon atoms are not particularly restricted, and may or may not have aromaticity.

Examples of the ring formed by A^{x} and A^{y} together may include rings shown below. The rings shown below are a moiety of:

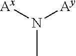

in the formula (I).

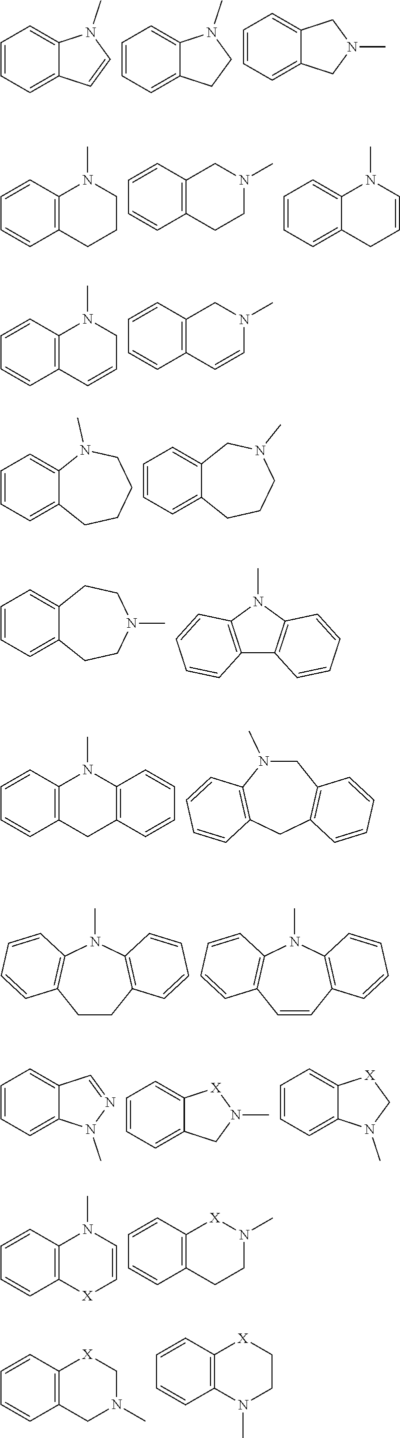

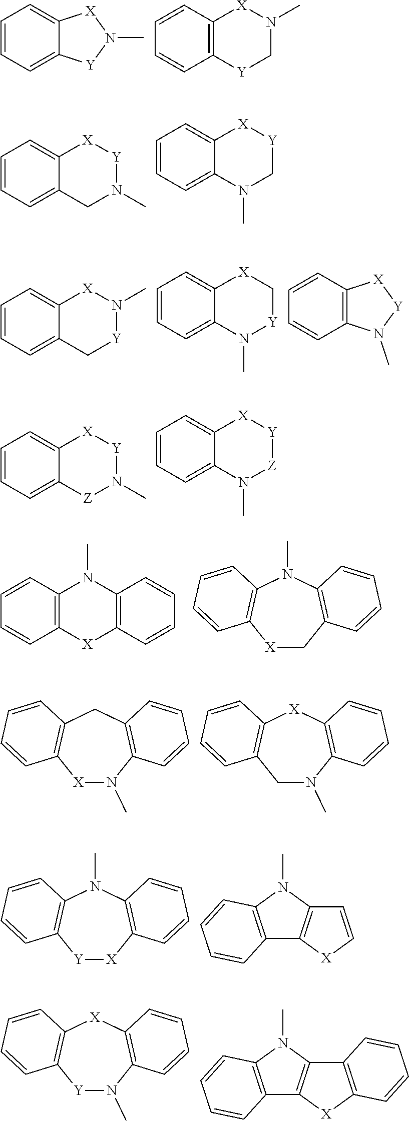

(In the formulae, X, Y, and Z have the same meanings as described above.)

The rings may have a substituent. Examples of the substituent may include those described as the substituent in the aromatic ring of A^{x}.

The total number of π electrons contained in A^{x} and A^{y} is preferably 4 or more, and more preferably 6 or more, and is preferably 24 or less, more preferably 20 or less, and particularly preferably 18 or less from the viewpoint of favorably expressing the desired effect of the present invention.

Examples of preferred combination of A^{x} and A^{y} may include the following combinations (α) and (β).

(α) a combination of A^{x} and A^{y} in which A^{x} is an aromatic hydrocarbon ring group of 4 to 30 carbon atoms or an aromatic heterocyclic group of 4 to 30 carbon atoms, A^{y} is a hydrogen atom, a cycloalkyl group of 3 to 8 carbon atoms, an aromatic hydrocarbon ring group of 6 to 12 carbon atoms optionally having a substituent (a halogen atom, a cyano group, an alkyl group of 1 to 6 carbon atoms, an alkoxy group of 1 to 6 carbon atoms, or a cycloalkyl group of 3 to 8 carbon atoms), an aromatic heterocyclic group of 3 to 9 carbon atoms optionally having a substituent (a halogen atom, an alkyl group of 1 to 6 carbon atoms, an alkoxy group of 1 to 6 carbon atoms, or a cyano group), an alkyl group of 1 to 20 carbon atoms optionally having a substituent, an alkenyl group of 1 to 20 carbon atoms optionally having a substituent, or an alkynyl group of 2 to 20 carbon atoms optionally having a substituent, and the substituent is any of a halogen atom, a cyano group, an alkoxy group of 1 to 20 carbon atoms, an alkoxy group of 1 to 12 carbon atoms that is substituted by an alkoxy group of 1 to 12 carbon atoms, a phenyl group, a cyclohexyl group, a cyclic ether group of 2 to 12 carbon atoms, an aryloxy group of 6 to 14 carbon atoms, a hydroxyl group, a benzodioxanyl group, a benzenesulfonyl group, a benzoyl group, and —SR¹⁰.

(β) a combination of A^{x} and A^{y} in which A^{x} and A^{y} together form an unsaturated heterocyclic ring or an unsaturated carbon ring. Herein, R¹⁰ has the same meanings as described above.

Examples of more preferred combination of A^{x} and A^{y} may include the following combination (γ).

(γ) a combination of A^{x} and A^{y} in which A^{x} is any of groups having the following structures, A^{y} is a hydrogen atom, a cycloalkyl group of 3 to 8 carbon atoms, an aromatic hydrocarbon ring group of 6 to 12 carbon atoms optionally having a substituent (a halogen atom, a cyano group, an alkyl group of 1 to 6 carbon atoms, an alkoxy group of 1 to 6 carbon atoms, or a cycloalkyl group of 3 to 8 carbon atoms), an aromatic heterocyclic group of 3 to 9 carbon atoms optionally having a substituent (a halogen atom, an alkyl group of 1 to 6 carbon atoms, an alkoxy group of 1 to 6 carbon atoms, or a cyano group), an alkyl group of 1 to 20 carbon atoms optionally having a substituent, an alkenyl group of 1 to 20 carbon atoms optionally having a substituent, or an alkynyl group of 2 to 20 carbon atoms optionally having a substituent, and the substituent is any of a halogen atom, a cyano group, an alkoxy group of 1 to 20 carbon atoms, an alkoxy group of 1 to 12 carbon atoms that is substituted by an alkoxy group of 1 to 12 carbon atoms, a phenyl group, a cyclohexyl group, a cyclic ether group of 2 to 12 carbon atoms, an aryloxy group of 6 to 14 carbon atoms, a hydroxyl group, a benzodioxanyl group, a benzenesulfonyl group, a benzoyl group, and —SR¹⁰. Herein, R¹⁰ has the same meanings as described above.

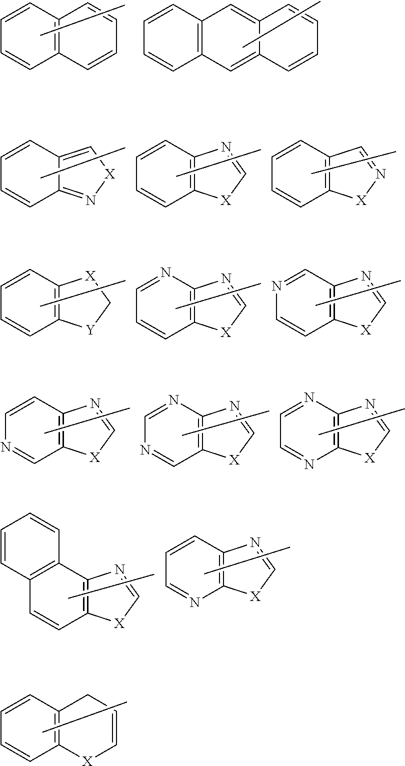

(In the formulae, X and Y have the same meanings as described above.)

Examples of particularly preferred combination of A^{x} and A^{y} may include the following combination (δ).

(δ) a combination of A^{x} and A^{y} in which A^{x} is any of groups having the following structures, A^{y} is a hydrogen atom, a cycloalkyl group of 3 to 8 carbon atoms, an aromatic hydrocarbon ring group of 6 to 12 carbon atoms optionally having a substituent (a halogen atom, a cyano group, an alkyl group of 1 to 6 carbon atoms, an alkoxy group of 1 to 6 carbon atoms, or a cycloalkyl group of 3 to 8 carbon atoms), an aromatic heterocyclic group of 3 to 9 carbon atoms optionally having a substituent (a halogen atom, an alkyl group of 1 to 6 carbon atoms, an alkoxy group of 1 to 6 carbon atoms, or a cyano group), an alkyl group of 1 to 20 carbon atoms optionally having a substituent, an alkenyl group of 1 to 20 carbon atoms optionally having a substituent, or an alkynyl group of 2 to 20 carbon atoms optionally having a substituent, and the substituent is any of a halogen atom, a cyano group, an alkoxy group of 1 to 20 carbon atoms, an alkoxy group of 1 to 12 carbon atoms that is substituted by an alkoxy group of 1 to 12 carbon atoms, a phenyl group, a cyclohexyl group, a cyclic ether group of 2 to 12 carbon atoms, an aryloxy group of 6 to 14 carbon atoms, a hydroxyl group, a benzodioxanyl group, a benzenesulfonyl group, a benzoyl group, and —SR¹⁰. In the following formulae, X has the same meanings as described above. Herein, R¹⁰ has the same meanings as described above.

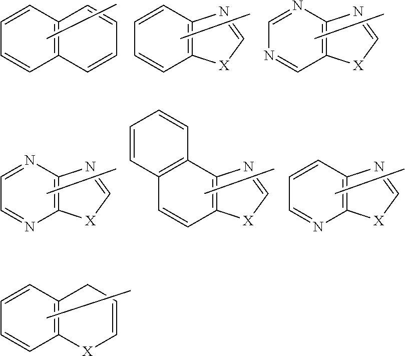

(In the formulae, X has the same meanings as described above.

In the formula (I) mentioned above, A1 is a trivalent aromatic group optionally having a substituent. The trivalent aromatic group may be a trivalent carbocyclic aromatic group or a trivalent heterocyclic aromatic group. From the viewpoint of favorably expressing the desired effect of the present invention, the trivalent aromatic group is preferably the trivalent carbocyclic aromatic group, more preferably a trivalent benzene ring group or a trivalent naphthalene ring group, and further preferably a trivalent benzene ring group or a trivalent naphthalene ring group that is represented by the following formula. In the following formulae, substituents Y¹ and Y² are described for the sake of convenience to clearly show a bonding state (Y¹ and Y² have the same meanings as described above, and the same applies to the following).

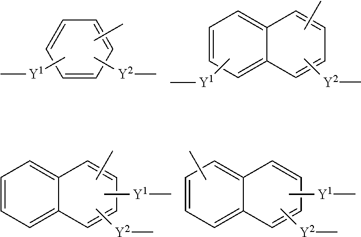

Among these, A¹ is more preferably a group represented by each of the following formulae (A11) to (A25), further preferably a group represented by the formula (A11), (A13), (A15), (A19), or (A23), and particularly preferably a group represented by the formula (A11) or (A23).

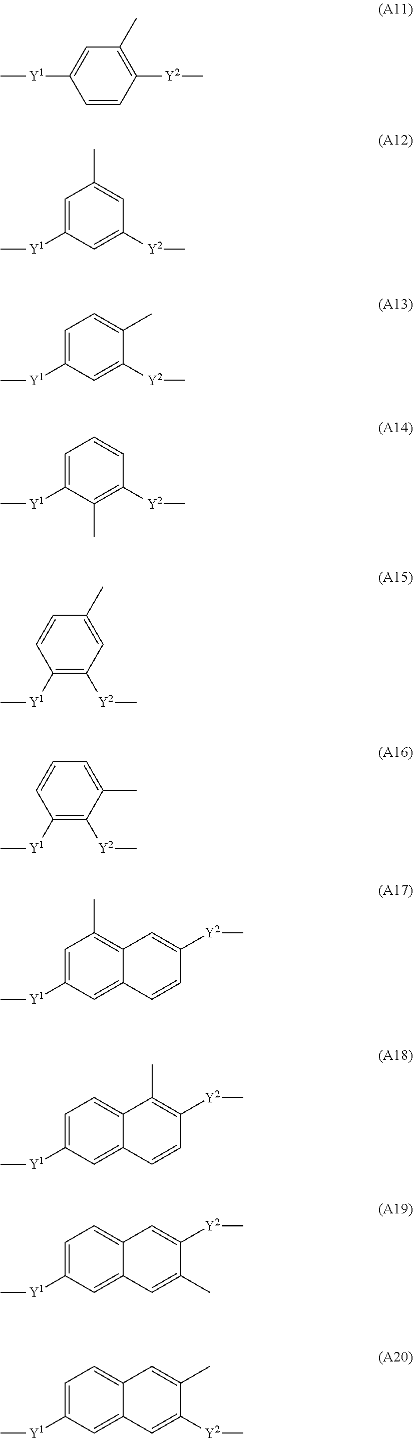

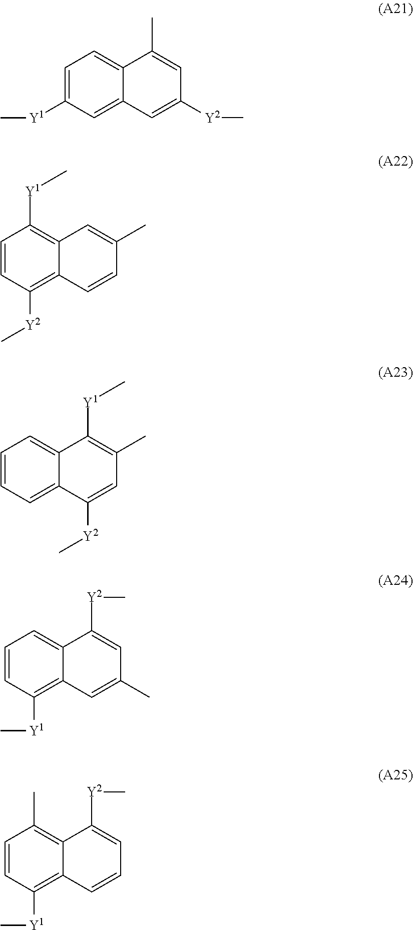

Examples of the substituent that may be included in the trivalent aromatic group of A¹ may include those described as the substituent in the aromatic ring of A^{x} described above. It is preferable that A¹ is a trivalent aromatic group having no substituent.

In the formula (I) mentioned above, A² and A³ are each independently a divalent alicyclic hydrocarbon group of 3 to 30 carbon atoms optionally having a substituent. Examples of the divalent alicyclic hydrocarbon group of 3 to 30 carbon atoms may include a cycloalkanediyl group of 3 to 30 carbon atoms, and a divalent alicyclic fused ring group of 10 to 30 carbon atoms.

Examples of the cycloalkanediyl group of 3 to 30 carbon atoms may include a cyclopropanediyl group; a cyclobutanediyl group, such as a cyclobutane-1,2-diyl group and a cyclobutane-1,3-diyl group; a cyclopentanediyl group, such as a cyclopentane-1,2-diyl group and a cyclopentane-1,3-diyl group; a cyclohexanediyl group, such as a cyclohexane-1,2-diyl group, a cyclohexane-1,3-diyl group, and a cyclohexane-1,4-diyl group; a cycloheptanediyl group, such as a cycloheptane-1,2-diyl group, a cycloheptane-1,3-diyl group, and a cycloheptane-1,4-diyl group; a cyclooctanediyl group, such as a cyclooctane-1,2-diyl group, a cyclooctane-1,3-diyl group, a cyclooctane-1,4-diyl group, and a cyclooctane-1,5-diyl group; a cyclodecanediyl group, such as a cyclodecane-1,2-diyl group, a cyclodecane-1,3-diyl group, a cyclodecane-1,4-diyl group, and a cyclodecane-1,5-diyl group; a cyclododecanediyl group, such as a cyclododecane-1,2-diyl group, a cyclododecane-1,3-diyl group, a cyclododecane-1,4-diyl group, and a cyclododecane-1,5-diyl group; a cyclotetradecanediyl group, such as a cyclotetradecane-1,2-diyl group, a cyclotetradecane-1,3-diyl group, a cyclotetradecane-1,4-diyl group, a cyclotetradecane-1,5-diyl group, and a cyclotetradecane-1,7-diyl group; and a cycloeicosanediyl group, such as a cycloeicosane-1,2-diyl group and a cycloeicosane-1,10-diyl group.

Examples of the divalent alicyclic fused ring group of 10 to 30 carbon atoms may include a decalindiyl group, such as a decalin-2,5-diyl group and a decalin-2,7-diyl group; an adamantanediyl group, such as an adamantane-1,2-diyl group and an adamantane-1,3-diyl group; and a bicyclo[2.2.1]heptanediyl group, such as a bicyclo[2.2.1]heptane-2,3-diyl group, a bicyclo[2.2.1]heptane-2,5-diyl group, and a bicyclo[2.2.1]heptane-2,6-diyl group.

The divalent alicyclic hydrocarbon groups may further have a substituent at any position. Examples of the substituent may include those described as the substituent in the aromatic ring of A^{x} described above.

Among these, A² and A³ are preferably a divalent alicyclic hydrocarbon group of 3 to 12 carbon atoms, more preferably a cycloalkanediyl group of 3 to 12 carbon atoms, further preferably a group represented by each of the following formulae (A31) to (A34).

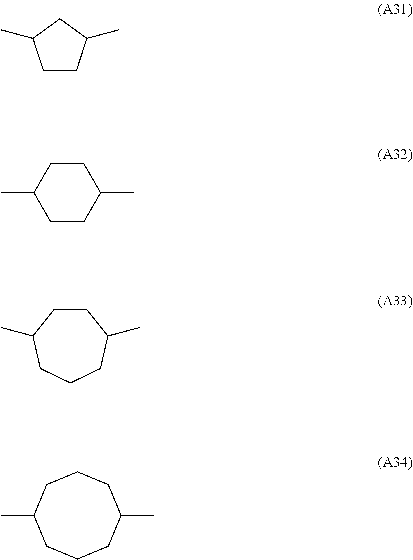

Particularly preferable is the group represented by the following formula (A32).

The divalent alicyclic hydrocarbon group of 3 to 30 carbon atoms may exist in forms of cis- and trans-stereoisomers that are on the basis of difference of stereoconfiguration of carbon atoms bonded to Y¹ and Y³ (or Y² and Y⁴). For example, when the group is a cyclohexane-1,4-diyl group, a cis-isomer (A32a) and a trans-isomer (A32b) may exist, as described below.

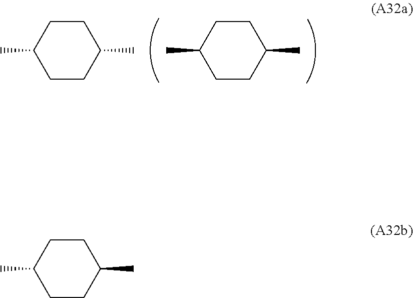

The aforementioned divalent alicyclic hydrocarbon group of 3 to 30 carbon atoms may be a cis-isomer, a trans-isomer, or an isomeric mixture of cis- and trans-isomers. Since the orientation is favorable, the group is preferably the trans-isomer or the cis-isomer, and more preferably the trans-isomer.

In the formula (I) mentioned above, A⁴ and A⁵ are each independently a divalent aromatic group of 6 to 30 carbon atoms optionally having a substituent. The aromatic group of A⁴ and A⁵ may be monocyclic or polycyclic. Specific preferable examples of A⁴ and A⁵ are as follows.

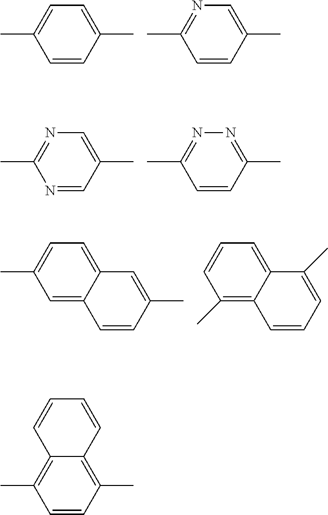

The divalent aromatic groups of A⁴ and A⁵ described above may have a substituent at any position. Examples of the substituent may include a halogen atom, a cyano group, a hydroxyl group, an alkyl group of 1 to 6 carbon atoms, an alkoxy group of 1 to 6 carbon atoms, a nitro group, and a —C(═O)—OR⁸b group. Herein, R^{8b} is an alkyl group of 1 to 6 carbon atoms. In particular, it is preferable that the substituent is a halogen atom, an alkyl group of 1 to 6 carbon atoms, or an alkoxy group. Of the halogen atoms, a fluorine atom is more preferable, of the alkyl groups of 1 to 6 carbon atoms, a methyl group, an ethyl group, and a propyl group are more preferable, and of the alkoxy groups, a methoxy group and an ethoxy group are more preferable.

Among these, from the viewpoint of favorably expressing the desired effect of the present invention, A⁴ and A⁵ are each independently preferably a group represented by the following formula (A41), (A42), and (A43) and optionally having a substituent, and particularly preferably the group represented by the formula (A41) and optionally having a substituent.

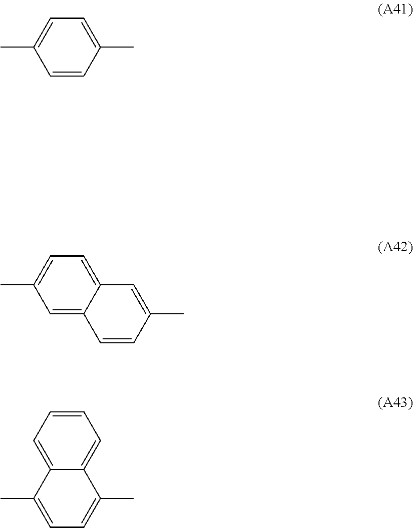

In the formula (I) mentioned above, Q¹ is a hydrogen atom or an alkyl group of 1 to 6 carbon atoms optionally having a substituent. Examples of the alkyl group of 1 to 6 carbon atoms optionally having a substituent may include the alkyl group of 1 to 6 carbon atoms among the alkyl groups of 1 to 20 carbon atoms optionally having a substituent that are described as A^{y} described above. Among these, Q¹ is preferably a hydrogen atom or an alkyl group of 1 to 6 carbon atoms, and more preferably a hydrogen atom or a methyl group.

In the formula (I) mentioned above, m is 0 or 1, and is particularly preferably 1.

The compound (I) may be produced by, for example, a reaction of a hydrazine compound with a carbonyl compound, described in International Publication No. WO2012/147904.

The liquid crystal composition may contain a polymerizable monomer. The “polymerizable monomer” refers to, among compounds that have polymerization ability and is capable of acting as a monomer, a compound other than the photopolymerizable liquid crystal compound with reverse wavelength distribution. As the polymerizable monomer, for example, a compound having one or more polymerizable groups per molecule may be used. With the polymerizable monomer having such a polymerizable group, polymerization can be achieved in formation of the optically anisotropic layer. When the polymerizable monomer is a cross-linkable monomer having two or more polymerizable groups per molecule, cross-linking polymerization can be achieved. Examples of the polymerizable group may include groups that are the same as Z¹—Y⁷— and Z²—Y⁸— groups in the compound (I). Specific examples thereof may include an acryloyl group, a methacryloyl group, and an epoxy group.

The polymerizable monomer itself may be liquid crystal, and may also be non-liquid crystal. Herein, the polymerizable monomer itself being “non-liquid crystal” means that when the polymerizable monomer itself is left at any temperature of room temperature to 200° C., the monomer does not exhibit orientation on a substrate film subjected to an orientation treatment. Whether the monomer exhibits orientation is determined by the presence or absence of light-dark contrast when a rubbing direction is rotated in a plane in cross-Nicol transmission observation with a polarizing microscope.

In the liquid crystal composition, the ratio of the polymerizable monomer is preferably 1 part by weight to 100 parts by weight, and more preferably 5 parts by weight to 50 parts by weight, relative to 100 parts by weight of the photopolymerizable liquid crystal compound with reverse wavelength distribution. When the ratio of the polymerizable monomer is appropriately adjusted within the range so as to exhibit desired reverse wavelength distribution, the reverse wavelength distribution can be easily controlled with precision.

The polymerizable monomer may be produced by a known production method. When the polymerizable monomer has a structure similar to the compound (I), it may be produced in accordance with a method for producing the compound (I).

The liquid crystal composition may contain a photopolymerization initiator. The photopolymerization initiator may be appropriately selected according to the type of polymerizable group of the polymerizable compound in the liquid crystal composition. For example, when the polymerizable group is radically polymerizable, a radical polymerization initiator may be used. When the polymerizable group is anionically polymerizable, an anionic polymerization initiator may be used. When the polymerizable group is cationically polymerizable, a cationic polymerization initiator may be used.

Examples of the radical polymerization initiator may include a photo-radical generator that is a compound that generates active species capable of initiating polymerization of the polymerizable compound by irradiation with light.

Examples of the photo-radical generator may include an acetophenone-based compound, a biimidazole-based compound, a triazine-based compound, an O-acyl oxime-based compound, an onium salt-based compound, a benzoin-based compound, a benzophenone-based compound, an α-diketone-based compound, a polynuclear quinone-based compound, a xanthone-based compound, a diazo-based compound, and an imide sulfonate-based compound, which are described in International publication WO2012/147904.

Examples of the anionic polymerization initiator may include an alkyl lithium compound; a monolithium salt or a monosodium salt of biphenyl, naphthalene, and pyrene; and a polyfunctional initiator such as a dilithium salt and a trilithium salt.

Examples of the cationic polymerization initiator may include a protonic acid such as sulfuric acid, phosphoric acid, perchloric acid, and trifluoromethanesulfonic acid; Lewis acid such as boron trifluoride, aluminum chloride, titanium tetrachloride, and tin tetrachloride; and a combination of an aromatic onium salt or an aromatic onium salt with a reducing agent.

Specific examples of commercially available photopolymerization initiators may include trade name Irgacure 907, trade name Irgacure 184, trade name Irgacure 369, trade name Irgacure 651, trade name Irgacure 819, trade name Irgacure 907, trade name Irgacure 379, trade name Irgacure 379EG, and trade name Irgacure OXE02, manufactured by BASF Corp.; and trade name Adekaoptomer N1919 manufactured by Adeka Corp.

As the polymerization initiator, one type thereof may be solely used, and two or more types thereof may also be used in combination at any ratio.

The ratio of the polymerization initiator in the liquid crystal composition is preferably 0.1 parts by weight to 30 parts by weight, and more preferably 0.5 parts by weight to 10 parts by weight, relative to 100 parts by weight of the polymerizable compound.

The liquid crystal composition may contain a surfactant for adjusting the surface tension. The surfactant is not particularly limited, and is preferably a nonionic surfactant. As the nonionic surfactant, a commercially available product may be used. For example, a nonionic surfactant that is an oligomer having a molecular weight of about several thousands may be used. Specific examples of the surfactant may include PolyFox “PF-151N”, “PF-636”, “PF-6320”, “PF-656”, “PF-6520”, “PF-3320”, “PF-651”, and “PF-652”, available from OMNOVA Solutions Inc.; Ftergent “FTX-209F”, “FTX-208G”, “FTX-204D”, and “601AD”, available from Neos Company; and SURFLON “KH-40” and “S-420” available from Seimi Chemical Co., Ltd. As the surfactant, one type thereof may be solely used, and two or more types thereof may also be used in combination at any ratio. The ratio of the surfactant in the liquid crystal composition is preferably 0.01 parts by weight to 10 parts by weight, and more preferably 0.1 parts by weight to 2 parts by weight, relative to 100 parts by weight of the polymerizable compound.

The liquid crystal composition may contain a solvent such as an organic solvent. Examples of the organic solvent may include a hydrocarbon solvent such as cyclopentane and cyclohexane; a ketone solvent such as cyclopentanone, cyclohexanone, methyl ethyl ketone, acetone, and methyl isobutyl ketone; an acetate ester solvent such as butyl acetate and amyl acetate; a halogenated hydrocarbon solvent such as chloroform, dichloromethane, and dichloroethane; an ether solvent such as 1,4-dioxane, cyclopentyl methyl ether, tetrahydrofuran, tetrahydropyran, 1,3-dioxolane, and 1,2-dimethoxyethane; an aromatic hydrocarbon solvent such as toluene, xylene, and mesitylene; and a mixture thereof. The boiling point of the solvent is preferably 60° C. to 250° C., and more preferably 60° C. to 150° C. from the viewpoint of excellent handleability. The amount of the solvent to be used is preferably 100 parts by weight to 1,000 parts by weight relative to 100 parts by weight of the polymerizable compound.

The liquid crystal composition may further contain an optional additive such as a metal, a metal complex, a dye, a pigment, a fluorescent material, a phosphorescent material, a leveling agent, a thixotropic agent, a gelator, a polysaccharide, an ultraviolet absorber, an infrared absorber, an antioxidant, an ion exchange resin, and a metal oxide such as titanium oxide. The ratio of each of the optional additives is preferably 0.1 parts by weight to 20 parts by weight relative to 100 parts by weight of the polymerizable compound.

[3. Method for Producing Optically Anisotropic Layer]

The optically anisotropic layer may be produced, for example, by a production method including:

Step (I): a step of applying the liquid crystal composition onto a substrate to obtain a layer of the liquid crystal composition,

Step (II): a step of orienting the photopolymerizable liquid crystal compound contained in the layer of the liquid crystal composition, and

Step (III): a step of curing the liquid crystal composition.

For example, the step (I) may be performed by applying the liquid crystal composition onto the substrate.

As the substrate, a long-length substrate is preferably used. When the long-length substrate is used, the liquid crystal composition can be continuously applied onto the substrate that is continuously conveyed. Therefore the use of the long-length substrate can achieve continuous production of the optically anisotropic layer, resulting in improved productivity.

When the liquid crystal composition is applied onto the substrate, it is preferable that the application is performed while an appropriate tensile force (usually 100 N/m to 500 N/m) is applied to the substrate to suppress flopping of the substrate during conveyance and maintain the planarity. The planarity is a swung amount of the substrate in its width direction and vertical direction perpendicular to the conveying direction, and is ideally 0 mm, but usually 1 mm or less.

As the substrate, a substrate film is usually used. As the substrate film, a film that can be used as a substrate for an optical layered body may be appropriately selected for use. In particular, from the viewpoint of usability of a multilayer film including the substrate film and the optically anisotropic layer as an optical film and elimination of the need of peeling of the optically anisotropic layer off the substrate film, it is preferable that the substrate film is a transparent film. Specifically, the total light transmittance of the substrate film is preferably 80% or more, more preferably 85% or more, and particularly preferably 88% or more. The total light transmittance of the substrate film may be measured within a wavelength range of 400 nm to 700 nm by using an ultraviolet-visible spectrophotometer.

The material for the substrate film is not particularly limited, and various resins may be used. Examples of the resins may include resins containing various types of polymers. Examples of the polymers may include an alicyclic structure-containing polymer, a cellulose ester, a polyvinyl alcohol, a polyimide, UV-transmitting acrylic, a polycarbonate, a polysulfone, a polyether sulfone, an epoxy polymer, a polystyrene, and a combination thereof. Among these, an alicyclic structure-containing polymer and a cellulose ester are preferable, and an alicyclic structure-containing polymer is more preferable from the viewpoint of transparency, low hygroscopicity, size stability, and light-weight property.

The alicyclic structure-containing polymer is a polymer having an alicyclic structure in a repeating unit. The alicyclic structure-containing polymer is usually an amorphous polymer. As the alicyclic structure-containing polymer, any of a polymer containing an alicyclic structure in its main chain and a polymer containing an alicyclic structure in its side chain may be used.

Examples of the alicyclic structure may include a cycloalkane structure and a cycloalkene structure. A cycloalkane structure is preferable from the viewpoint of thermal stability.

The number of carbon atoms constituting the repeating unit of one alicyclic structure is not particularly limited, and is preferably 4 or more, more preferably 5 or more, and particularly preferably 6 or more, and is preferably 30 or less, more preferably 20 or less, and particularly preferably 15 or less.

The ratio of the repeating unit having the alicyclic structure in the alicyclic structure-containing polymer is appropriately selected according to the purpose of use, and is preferably 50% by weight or more, more preferably 70% by weight or more, and particularly preferably 90% by weight or more. When the ratio of the repeating unit having an alicyclic structure is increased as described above, heat resistance of the substrate film can be enhanced.

Examples of the alicyclic structure-containing polymer may include (1) a norbornene polymer, (2) a monocyclic cyclic-olefin polymer, (3) a cyclic conjugated diene polymer, (4) a vinyl alicyclic hydrocarbon polymer, and hydrogenated products thereof. Among these, from the viewpoint of transparency and moldability, a norbornene polymer is preferable.

Examples of the norbornene polymer may include a ring-opening polymer of a norbornene monomer, a ring-opening copolymer of a norbornene monomer with another ring-opening copolymerizable monomer, and hydrogenated products thereof; and an addition polymer of a norbornene monomer, and an addition copolymer of a norbornene monomer with another copolymerizable monomer. Among these, a hydrogenated product of a ring-opening polymer of a norbornene monomer is particularly preferable from the viewpoint of transparency.

The aforementioned alicyclic structure-containing polymer is selected from publicly known polymers disclosed in, for example, Japanese Patent Application Laid-Open No. 2002-321302 A.

The glass transition temperature of the alicyclic structure-containing polymer is preferably 80° C. or higher, and more preferably in a range of 100° C. to 250° C. The alicyclic structure-containing polymer having the glass transition temperature falling within such a range is not prone to cause deformation and stress during use under high temperature. Thus, the alicyclic structure-containing polymer has excellent durability.

The weight-average molecular weight (Mw) of the alicyclic structure-containing polymer is preferably 10,000 to 100,000, more preferably 25,000 to 80,000, and further preferably 25,000 to 50,000. When the weight-average molecular weight falls within such a range, mechanical strength and molding processability of the substrate film are highly balanced and suitable. The weight-average molecular weight described above may be measured as a polyisoprene-equivalent value by gel permeation chromatography (hereinafter, abbreviated as “GPC”) using cyclohexane as a solvent. When the resin is not soluble in the solvent, the weight-average molecular weight may be measured as a polystyrene-equivalent value by GPC using toluene as the solvent.

The molecular weight distribution (weight-average molecular weight (Mw)/number-average molecular weight (Mn)) of the alicyclic structure-containing polymer is preferably 1 or more, and more preferably 1.2 or more, and is preferably 10 or less, more preferably 4 or less, and particularly preferably 3.5 or less.

When a resin containing the alicyclic structure-containing polymer is used as the material for the substrate film, the thickness of the substrate film is preferably 1 μm to 1,000 μm, more preferably 5 μm to 300 μm, and particularly preferably 30 μm to 100 μm from the viewpoint of improved productivity, a decrease in thickness, and weight saving.

The resin containing the alicyclic structure-containing polymer may be composed of only the alicyclic structure-containing polymer, or may contain any compounding agent as long as the effects of the present invention are not significantly impaired. The ratio of the alicyclic structure-containing polymer in the resin containing the alicyclic structure-containing polymer is preferably 70% by weight or more, and more preferably 80% by weight or more.

Specific suitable examples of the resin containing the alicyclic structure-containing polymer may include “ZEONOR 1420” and “ZEONOR 1420R” manufactured by ZEON Corporation.

A typical cellulose ester is a lower fatty acid ester of cellulose (for example, cellulose acetate, cellulose acetate butyrate, and cellulose acetate propionate). A lower fatty acid means a fatty acid of 6 or less carbon atoms per molecule. Cellulose acetate includes triacetylcellulose (TAC) and cellulose diacetate (DAC).

The acetylation degree of cellulose acetate is preferably 50% to 70%, and particularly preferably 55% to 65%. The weight-average molecular weight is preferably 70,000 to 120,000, and particularly preferably 80,000 to 100,000. The aforementioned cellulose acetate may be esterified solely by acetic acid, and may also be additionally esterified partially by a fatty acid such as propionic acid or butyric acid. The resin constituting the substrate film may contain the cellulose acetate and a cellulose ester other than the cellulose acetate (such as cellulose propionate and cellulose butyrate) in combination. In this case, it is preferable that the entirety of the cellulose esters satisfy the aforementioned acetylation degree.

When a film of triacetylcellulose is used as the substrate film, it is particularly preferable that such a film is a triacetylcellulose film formed using triacetylcellulose dope that is prepared by dissolving triacetylcellulose in a solvent essentially free of dichloromethane by a low-temperature dissolution method or a high-temperature dissolution method from the viewpoint of environmental conservation. The film of triacetylcellulose may be prepared by a co-casting method. The co-casting method may be performed as follows. A solution (dope) containing raw material flakes of triacetylcellulose and a solvent, and if necessary, an optional additive is prepared, the dope is cast on a support from a dope supplying device (die), and the cast material is dried to some extent. When rigidity is imparted, the cast material is peeled as a film off the support, and the film is further dried to remove the solvent. Examples of the solvent in which the raw material flakes are dissolved may include a halogenated hydrocarbon solvent (dichloromethane, etc.), an alcohol solvent (methanol, ethanol, butanol, etc.), an ester solvent (methyl formate, methyl acetate, etc.), and an ether solvent (dioxane, dioxolane, diethyl ether, etc.). Examples of the additive contained in the dope may include a retardation-increasing agent, a plasticizer, an ultraviolet absorber, a deterioration inhibitor, a lubricant, and a peeling promoter. Examples of the support on which the dope is cast may include a horizontal endless metal belt and a rotating drum. During casting, a single dope may be cast in a single layer, and co-casting of a plurality of layers may also be performed. In a case of co-casting of a plurality of layers, for example, a plurality of dopes may be successively cast so that a layer of low-concentration cellulose ester dope and a layer of high-concentration cellulose ester dope in contact with the front and back sides of the layer of the low-concentration cellulose ester dope are formed. Examples of a method for drying the film to remove the solvent may include a method for conveying the film to pass the film through a drying unit of which the interior portion is set to conditions suitable for drying.

Preferable examples of the film of triacetylcellulose may include “TAC-TD80U” manufactured by Fuji Film Corporation, and those which have been publicly laid open by Journal of Technical Disclosure No. 2001-1745. The thickness of the film of triacetylcellulose is not particularly limited, and is preferably 20 μm to 150 μm, more preferably 40 μm to 130 μm, and further preferably 70 μm to 120 μm.

As the substrate, a substrate having an orientation-regulating force may be used. The orientation-regulating force of the substrate refers to a property of the substrate that is capable of orienting the photopolymerizable liquid crystal compound in the liquid crystal composition having been applied onto the substrate.

The orientation-regulating force may be imparted to a member such as the film serving as a material of the substrate by a treatment for imparting the orientation-regulating force. Examples of such a treatment may include a stretching treatment and a rubbing treatment.

In a preferable aspect, the substrate is a stretched film. When such a stretched film is used, the stretched film may be a substrate having an orientation-regulating force according to the stretching direction.

The stretching direction of the stretched film may be any direction. Therefore, stretching may be performed by only oblique stretching (stretching in a direction that is not parallel to the lengthwise direction and the width direction of the substrate), only lateral stretching (stretching in the width direction of the substrate), or only longitudinal stretching (stretching in the lengthwise direction of the substrate). These methods of stretching may be performed in combination. The stretching ratio may be appropriately set within a range that generates an orientation-regulating force on a surface of the substrate. When a resin having a positive intrinsic birefringence is used as the material for the substrate, molecules are oriented in the stretching direction to exhibit an orientation axis in the stretching direction. The stretching may be performed by a known stretching machine such as a tenter stretching machine.

In a further preferable aspect, the substrate is an obliquely stretched film. That is, the substrate is a long-length film, and further preferably a film stretched in a direction that is not parallel to the lengthwise direction nor parallel to the width direction of the film.

When the substrate is an obliquely stretched film, the angle formed between the stretching direction and the width direction of the stretched film may be specifically larger than 0° and less than 90°. When such an obliquely stretched film is used, an optical film such as a circularly polarizing plate can be efficiently produced by transferring the optically anisotropic layer to a long-length linear polarizer by a roll-to-roll process, followed by layering.

In a certain aspect, the angle formed between the stretching direction and the width direction of the stretched film may be set within a specific range of preferably 15°±5°, 22.5°±5°, 45°±5°, or 75°±5°, more preferably 15°±4°, 22.5°±4°, 45°±4°, or 75°±4°, and further preferably 15°±3°, 22.5°±3°, 45°±3°, or 75°±3°. When such an angle relationship is satisfied, the optically anisotropic layer can be used as a material capable of efficiently producing a circularly polarizing plate.

Examples of a method for applying the liquid crystal composition may include a curtain coating method, an extrusion coating method, a roll coating method, a spin coating method, a dip coating method, a bar coating method, a spray coating method, a slide coating method, a printing coating method, a gravure coating method, a die coating method, a gap coating method, and a dipping method. The thickness of the layer of the liquid crystal composition to be applied may be appropriately set according to a desired thickness required for the optically anisotropic layer.

After the step (I), the step (II) of orienting the photopolymerizable liquid crystal compound is performed. In the step (II), the photopolymerizable liquid crystal compound contained in the layer of the liquid crystal composition is oriented in an orientation direction according to the orientation-regulating force of the substrate. For example, when the stretched film is used as the substrate, the photopolymerizable liquid crystal compound contained in the layer of the liquid crystal composition is oriented in parallel to the stretching direction of the stretched film. When the long-length substrate film is used as the substrate, it is preferable that the photopolymerizable liquid crystal compound is oriented in an oblique direction that is not the lengthwise direction nor width direction of the substrate. With the layer of the liquid crystal composition containing the photopolymerizable liquid crystal compound oriented in the oblique direction, an optically anisotropic layer of which the orientation direction is usually the oblique direction is obtained. Therefore, an optical film such as a circularly polarizing plate can be efficiently produced by transferring the optically anisotropic layer to a long-length linear polarizer by a roll-to-roll process, followed by layering.

The step (II) may be achieved immediately by applying, but if necessary, the step (II) may be achieved by an orientation treatment such as warming after applying. Conditions for the orientation treatment may be appropriately set according to the properties of the liquid crystal composition to be used. For example, the conditions may be at 50° C. to 160° C. for 30 seconds to 5 minutes.

The step (III) may be performed immediately after the step (II). Alternatively, a step of drying the layer of the liquid crystal composition may be performed at any stage such as before the step (III) and after the step (II), if necessary. Such drying may be achieved by a drying method such as natural drying, drying by heating, drying under reduced pressure, and drying by heating under reduced pressure. By the drying, the solvent can be removed from the layer of the liquid crystal composition.

In the step (III), curing of the layer of the liquid crystal composition is achieved by polymerizing a polymerizable compound such as the photopolymerizable liquid crystal compound contained in the liquid crystal composition, to thereby obtain the optically anisotropic layer. As a method of polymerizing the polymerizable compound, a method that is suitable for properties of the components of the liquid crystal composition, such as the polymerizable compound and the polymerization initiator, may be appropriately selected. For example, irradiation with light is preferable. The light for irradiation herein may include visible light, ultraviolet light, and infrared light. Among these, irradiation with ultraviolet light is preferable in terms of easy operation.

The irradiation intensity of ultraviolet light during irradiation with ultraviolet light in the step (III) is preferably in a range of 0.1 mW/cm² to 1,000 mW/cm², and more preferably in a range of 0.5 mW/cm² to 600 mW/cm². The irradiation time of ultraviolet light is preferably in a range of 1 second to 300 seconds, and more preferably in a range of 5 seconds to 100 seconds. The integrated amount of ultraviolet light (mJ/cm²) is calculated by the irradiation intensity of ultraviolet light (mW/cm²)×the irradiation time of ultraviolet light (second). As an irradiation source of ultraviolet light, for example, a high-pressure mercury vapor lamp, a metal halide lamp, or a low-pressure mercury vapor lamp may be used.

In order to decrease the residual monomer ratio in the optically anisotropic layer, it is preferable to control the conditions for polymerizing the polymerizable compound in the step (III). For example, it is preferable that the temperature of the layer of the liquid crystal composition is adjusted in the step (III).

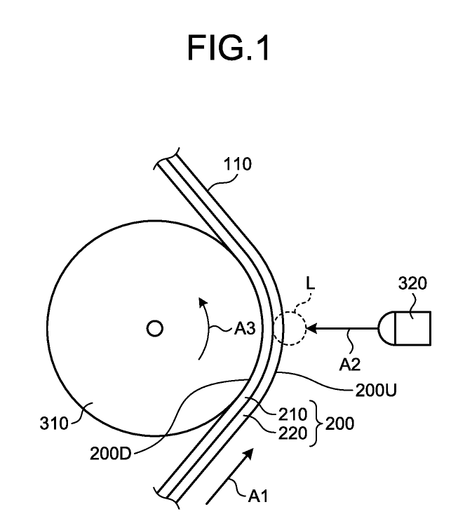

FIG. 1 is a schematic diagram schematically illustrating a state of the step (III) of curing a layer 220 of a liquid crystal composition formed on a substrate film 210 to obtain an optically anisotropic layer 110 in an example of a method for producing the optically anisotropic layer 110.

As shown in FIG. 1, the temperature of the layer 220 of the liquid crystal composition in the step (III) may be adjusted by performing the step (III) with the substrate film 210 supported by a back roller 310, and adjusting the temperature of the back roller 310.

The back roller 310 is a roller for supporting the substrate film 210 from the back side of a surface 200U to be irradiated during irradiation with light. In FIG. 1, a layered body 200 containing the substrate film 210 and the layer 220 of the liquid crystal composition provided on the substrate film 210 is conveyed in a direction of an arrow A1 with maintaining its planarity. The layered body 200 is supported by the back roller 310 rotated in a direction of an arrow A3 at a position L with a surface 200D on the substrate film 210 side in contact with the back roller 310, and conveyed. At the position L, the layer 220 of the liquid crystal composition is irradiated with ultraviolet light in a direction of an arrow A2 from a light source 320, resulting in curing. The layer 220 of the liquid crystal composition is thus cured, so that the optically anisotropic layer 110 is obtained. In this case, the temperature of the back roller 310 may be flexibly adjusted to achieve curing so that the residual monomer ratio is low. In general, as the temperature of the back roller 310 is higher, the residual monomer ratio tends to decrease. However, optimal temperature varies depending on other conditions. Therefore, it is preferable to experimentally determine the temperature at which the residual monomer ratio decreases. Further, reduction of the residual monomer ratio may also be achieved by increase in the irradiation dose of light, or increase in the amount of the polymerization initiator.

The upper limit of the temperature of the back roller 310 is preferably equal to or lower than the glass transition temperature (Tg) of the substrate film 210 from the viewpoint of preventing deformation of the substrate film 210. Specifically, the temperature of the back roller 310 is preferably 150° C. or lower, more preferably 100° C. or lower, and particularly preferably 80° C. or lower. The lower limit of the temperature of the back roller 310 may be 15° C. or higher. Therefore, it is preferable that the temperature at which the residual monomer ratio decreases is experimentally determined within this temperature range.

When the step (III) is performed under an inert gas atmosphere such as a nitrogen atmosphere, the residual monomer ratio is likely to decrease as compared with the step (III) that is performed in air. Therefore, it is preferable that the step (III) is performed under such an inert gas atmosphere.

During polymerization in the step (III), the photopolymerizable liquid crystal compound is usually polymerized with the orientation of molecules maintained. By the polymerization, the optically anisotropic layer containing cured liquid crystal molecules oriented in a direction parallel to the orientation direction of the photopolymerizable liquid crystal compound contained in the liquid crystal composition before curing is obtained. For example, when the stretched film is used as the substrate, the optically anisotropic layer having an orientation direction parallel to the stretching direction of the stretched film can be obtained. Being parallel herein refers to that a difference between the stretching direction of the stretched film and the orientation direction of the cured liquid crystal molecules is usually ±3°, preferably ±1°, and ideally 0°.

In the optically anisotropic layer produced by the production method described above, it is preferable that the cured liquid crystal molecules obtained from the photopolymerizable liquid crystal compound have orientation regularity in which the molecules are horizontally oriented with respect to the substrate film. For example, when a substrate film having an orientation-regulating force is used, the cured liquid crystal molecules can be horizontally oriented in the optically anisotropic layer. Herein, that the cured liquid crystal molecules are “horizontally oriented” to the substrate film mean that the average direction of long-axis directions of mesogens of the cured liquid crystal molecules is aligned in one direction parallel to or substantially parallel to a film surface (for example, the angle between the direction and the film surface is within 5°). Whether the cured liquid crystal molecules are horizontally oriented and the alignment direction may be confirmed by measurement using a phase difference meter such as AxoScan (manufactured by Axometrics, Inc.).

In particular, when the cured liquid crystal molecules are those obtained by polymerizing a photopolymerizable liquid crystal compound having a rod-shaped molecular structure, the long-axis direction of the mesogen of the photopolymerizable liquid crystal compound is usually the long-axis direction of the mesogens of the cured liquid crystal molecules. In a case wherein a plurality of types of mesogens having different orientation directions exist in the optically anisotropic layer such as in a case wherein the photopolymerizable liquid crystal compound with reverse wavelength distribution is used as the polymerizable liquid crystal compound, a direction in which the long-axis direction of the mesogen of the longest type among the mesogens is aligned is usually the alignment direction.

The aforementioned production method may further include an optional step. For example, the production method descried above may include a step of peeling the optically anisotropic layer off the substrate.

[5. Optically Anisotropic Layered Body]

The optically anisotropic layer may be used alone or may be used in combination with an optional film as an optical film. In particular, it is preferable that the optically anisotropic layer is used in combination with a phase difference layer for an optically anisotropic layered body.

The optically anisotropic layered body includes the optically anisotropic layer and the phase difference layer. In the optically anisotropic layered body, the optically anisotropic layer and the phase difference layer may be bonded to each other with an optional layer such as an adhesive layer interposed therebetween or directly without the intervention of the optional layer. As the phase difference layer, a layer having refractive indexes satisfying nz>nx≥ny is used. When the optically anisotropic layered body including the optically anisotropic layer and the phase difference layer in combination is combined with a linear polarizer, a circularly polarizing plate that can function as an anti-reflective film by which reflection of outside light is suppressed when a screen is viewed not only in a front direction but also in an inclined direction can be realized.

In particular, it is preferable that the optically anisotropic layer is a λ/4 wave plate, and the in-plane retardation Re(B550) of the phase difference layer at a wavelength of 550 nm and the retardation Rth(B550) in the thickness direction of the phase difference layer at a wavelength of 550 nm satisfy the following formulae (5) and (6):

Re(B550)≤10 nm (5), and

−100 nm≤Rth(B550)≤−20 nm (6).

Specifically, the in-plane retardation Re(B550) of the phase difference layer is preferably 0 nm to 10 nm, more preferably 0 nm to 5 nm, and particularly preferably 0 nm. The retardation Rth(B550) in the thickness direction of the phase difference layer is preferably −100 nm or more, more preferably −90 nm or more, and particularly preferably −80 nm or more, and is preferably −20 nm or less, more preferably −35 nm or less, and particularly preferably −50 nm or less.

When the optically anisotropic layer is a λ/4 wave plate and the in-plane retardation Re(B550) and retardation Rth(B550) in the thickness direction of the phase difference layer fall within the aforementioned ranges, a circularly polarizing plate including the optically anisotropic layered body can function as an anti-reflective film by which reflection of outside light is efficiently suppressed when a screen is viewed in an inclined direction.

As the phase difference layer, for example, a stretched film layer described in Japanese Patent No. 2818983 B or Japanese Patent Application Laid-Open No. Hei. 6-88909 A may be used. It is preferable that a layer containing the following compounds (P1) to (P7) is used since therewith a thin film can be formed. The following compounds (P1) to (P7) may be used to easily obtain the phase difference layer. A composition containing the compounds (P1) to (P7) and a solvent is applied and dried, to obtain the phase difference layer. As the compounds (P1) to (P7), one type thereof may be solely used, and two or more types thereof may also be used in combination at any ratio.

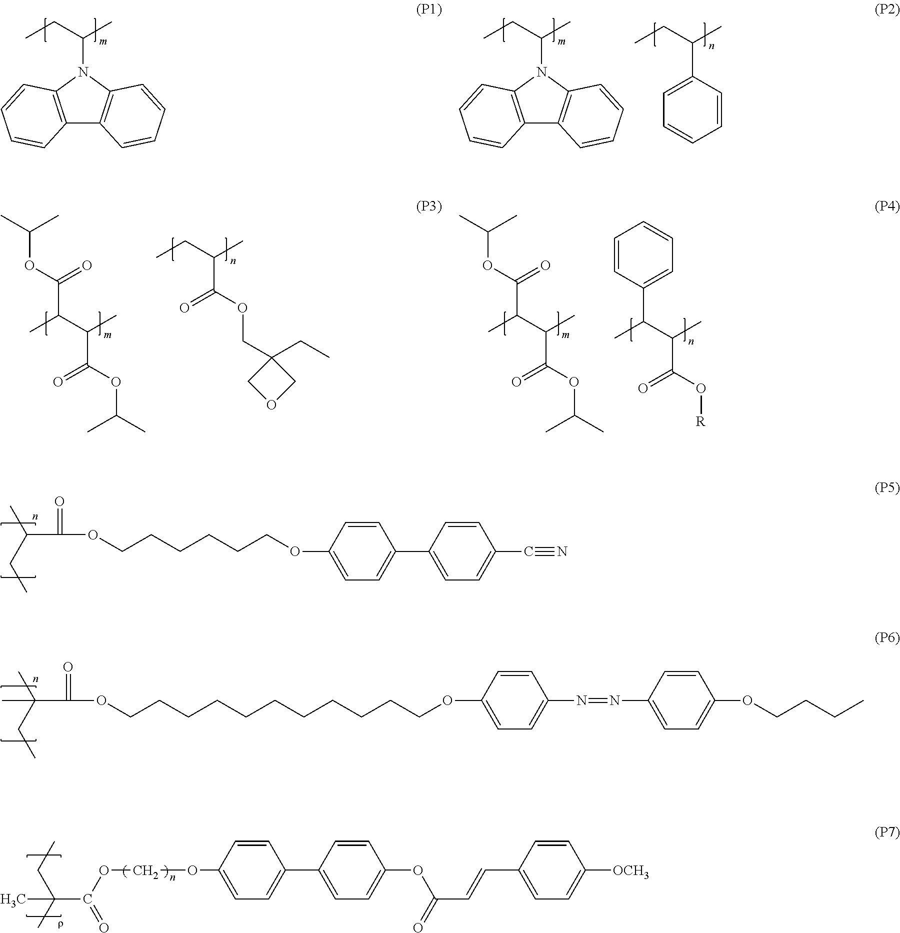

The compound (P1) is poly(N-vinyl carbazole). In the compound (P1), m is the number of repeating unit. The weight-average molecular weight of the compound (P1) is usually 5,000 to 100,000. The compound (P1) can be purchased as PV series from Maruzen Petrochemical Co., Ltd.

The compound (P2) is a copolymer of poly(N-vinyl carbazole) with polystyrene. In the compound (P2), m is 30 to 100, and n is 30 to 100. Regarding the compound (P2), Japanese Patent Application Laid-Open No. 2010-126583 A may be referred to.

The compound (P3) is a copolymer of diisopropyl fumarate with 3-ethyl-3-oxetanylmethyl acrylate. In the compound (P3), m is 20 to 120, and n is 20 to 120. Regarding the compound (P3), Japanese Patent Application Laid-Open No. 2011-137051 A may be referred to.

The compound (P4) is a copolymer of diisopropyl fumarate with a cinnamic acid ester. In the compound (P4), m and n are the number of repeating unit. The weight-average molecular weight of the compound (P4) is usually 10,000 to 500,000. Regarding the compound (P4), International publication WO2014/013982 may be referred to.

The compound (P5) is poly(6-(4-cyanobiphenyl-4-yloxy)hexyl methacrylate). In the compound (P5), n is 20 to 150.

The compound (P6) is poly[11-(4-4(4-butylphenylazo)phenoxy)-undecyl methacrylate)]. In the compound (P6), n is 20 to 100.

In the compound (P7), n is 10, and ρ is 20 to 100. Regarding the compound (P7), Document “Macromolecules 2015, vol. 48, pp. 2203-2210” may be referred to.

The thickness of the phase difference layer may be optionally set within a range in which a desired retardation is obtained. Specifically, the thickness of the phase difference layer is preferably 2 μm or more, more preferably 5 μm or more, and particularly preferably 7 μm or more, and is preferably 15 μm or less, more preferably 12 μm or less, and particularly preferably 10 μm or less.

The optically anisotropic layered body may further include an optional layer in combination with the optically anisotropic layer and the phase difference layer. Examples of the optional layer may include an adhesion layer and a hardcoat layer.

The method for producing the optically anisotropic layered body is not limited, and for example, the optically anisotropic layered body may be produced by the following production method 1 or 2.

Production Method 1:

A production method including:

a step of applying a coating composition containing one or more of the compounds (P1) to (P7) and a solvent onto the optically anisotropic layer to form a layer of the coating composition; and

a step of drying the layer of the coating composition to form the phase difference layer, thereby obtaining the optically anisotropic layered body.

Production Method 2:

A production method including:

a step of applying a coating composition containing one or more of the compounds (P1) to (P7) and a solvent onto an optional support to form a layer of the coating composition;

a step of drying the layer of the coating composition to form the phase difference layer; and

a step of bonding the phase difference layer to the optically anisotropic layer to obtain the optically anisotropic layered body.

It is preferable that the solvent contained in the coating composition is a solvent capable of dissolving the compounds (P1) to (P7). Examples thereof may include N-methyl pyrrolidone (NMP), methyl ethyl ketone (MEK), methyl isopropyl ketone (MIPK), methyl isobutyl ketone (MIBK), toluene, and 1,3-dioxolane. As the solvent, one type thereof may be solely used, and two or more types thereof may also be used in combination at any ratio.

It is preferable that the amount of the solvent is adjusted so that the solid content concentration of the coating composition falls within a desired range. The solid content concentration of the coating composition is preferably 6% by weight or more, more preferably 8% by weight or more, and particularly preferably 10% by weight or more, and is preferably 20% by weight or less, more preferably 18% by weight or less, and particularly preferably 15% by weight or less. When the solid content concentration of the coating composition falls within the aforementioned range, the phase difference layer having the aforementioned retardation can be easily formed.

In addition to the compounds (P1) to (P7) and the solvent, the coating composition may contain an optional component in a range wherein the phase difference layer having a desired retardation can be formed. Examples of the optional component may include triphenylphosphine (plasticizer). As the optional component, one type thereof may be solely used, and two or more types thereof may also be used in combination at any ratio.

The coating composition may be applied onto the optically anisotropic layer as in the production method 1, or may be applied onto a support other than the optically anisotropic layer as in the production method 2. As the support, a film is usually used. In particular, a long-length film is preferably used for efficiently producing the phase difference layer. A long-length resin film is preferably used.

Examples of the method for applying the coating composition may include a curtain coating method, an extrusion coating method, a roll coating method, a spin coating method, a dip coating method, a bar coating method, a spray coating method, a slide coating method, a printing coating method, a gravure coating method, a die coating method, a gap coating method, and a dipping method.

By the application of the coating composition, the layer of the coating composition is obtained. By the drying of the layer of the coating composition, the phase difference layer can be obtained. The method for drying the layer of the coating composition may be any method. For example, a drying method such as natural drying, drying by heating, drying under reduced pressure, and drying by heating under reduced pressure may be employed.

When the coating composition is applied onto the optically anisotropic layer as in the production method 1, the phase difference layer is formed on the optically anisotropic layer by drying the layer of the coating composition. As a result, the optically anisotropic layered body is obtained.

When the coating composition is applied onto the support as in the production method 2, the phase difference layer is formed on the support by drying the layer of the coating composition. The formed phase difference layer is bonded to the optically anisotropic layer, to obtain the optically anisotropic layered body. In the bonding, an appropriate adhesive may be used. As the adhesive, for example, the same adhesive as an adhesive used for a circularly polarizing plate described later may be used.

The method for producing the optically anisotropic layered body may include an optional step in addition to the aforementioned steps. For example, the production method may include steps of peeling the support, and providing an optional layer such as a hardcoat layer.

[4. Circularly Polarizing Plate]

The optically anisotropic layer or the optically anisotropic layered body may be used as a member constituting a circularly polarizing plate in combination with a linear polarizer. The circularly polarizing plate includes the linear polarizer and the optically anisotropic layer, or the linear polarizer and the optically anisotropic layered body.

The circularly polarizing plate may further include an adhesion layer to bond the linear polarizer and the optically anisotropic layer or to bond the linear polarizer and the optically anisotropic layered body. The circularly polarizing plate usually includes the linear polarizer, the adhesion layer, and the optically anisotropic layer in this order, or the linear polarizer, the adhesion layer, and the optically anisotropic layered body in this order. In this case, the circularly polarizing plate may have only one layer or two or more layers of each of the linear polarizer, the adhesion layer, the optically anisotropic layer, and the optically anisotropic layered body. For example, the circularly polarizing plate may have a layer structure of (linear polarizer)/(adhesion layer)/(optically anisotropic layer or optically anisotropic layered body), or a layer structure of (linear polarizer)/(adhesion layer)/(optically anisotropic layer or optically anisotropic layered body)/(adhesion layer)/(optically anisotropic layer or optically anisotropic layered body).

Examples of specific aspects of the circularly polarizing plate may include two aspects described below. Herein, in circularly polarizing plates (i) and (ii) described below, the optically anisotropic layer may be included in the optically anisotropic layered body.

Circularly polarizing plate (i): A circularly polarizing plate in which the optically anisotropic layer is a λ/4 wave plate, and the direction of the slow axis of the λ/4 wave plate relative to the polarized light transmission axis or polarized light absorption axis of the linear polarizer is 45° or an angle close to 45°. Herein, “45° or an angle close to 45°” may be, for example, 45°±5°, preferably 45°±4°, and more preferably 45°±3°.

Circularly polarizing plate (ii): a circularly polarizing plate obtained by bonding a λ/4 wave plate, a λ/2 wave plate, and the linear polarizer, wherein the λ/4 wave plate, the λ/2 wave plate, or both of the plates are the optically anisotropic layer.

In the circularly polarizing plate (ii), a relationship of the slow axis of the λ/4 wave plate, the slow axis of the λ/2 wave plate, and the polarized light absorption axis of the linear polarizer may be various known relationships. For example, the relationship may be a relationship in which the direction of the slow axis of the λ/2 wave plate relative to the direction of the polarized light absorption axis of the linear polarizer is 15° or an angle close to 15°, and the direction of the slow axis of the λ/4 wave plate relative to the direction of the polarized light absorption axis of the linear polarizer is 75° or an angle close to 75°. Herein, “15° or an angle close to 15°” may be, for example, 15°±5°, preferably 15°±4°, and more preferably 15°±3°. Further, “75° or an angle close to 75°” may be, for example, 75°±5°, preferably 75°±4°, and more preferably 75°±3°. With such an aspect, the circularly polarizing plate may be used as a broadband anti-reflective film for an organic electroluminescent display device.

In a certain product according to the present invention (circularly polarizing plate, etc.), angular relationship of directions of in-plane optical axes (slow axis, polarized light transmission axis, polarized light absorption axis, etc.) and geometric directions (the lengthwise direction and width direction of the film, etc.) is defined in a manner such that a shift in a certain direction is positive, and a shift in the other direction is negative. The positive and negative directions are commonly defined in components of the product. For example, in a circularly polarizing plate, “the direction of the slow axis of the λ/2 wave plate relative to the direction of the polarized light absorption axis of the linear polarizer is 15° and the direction of the slow axis of the λ/4 wave plate relative to the direction of the polarized light absorption axis of the linear polarizer is 75°” represents two cases described below:

When the circularly polarizing plate is observed from one face thereof, the direction of the slow axis of the λ/2 wave plate shifts clockwise by 15° from the direction of the polarized light absorption axis of the linear polarizer and the direction of the slow axis of the λ/4 wave plate shifts clockwise by 75° from the direction of the polarized light absorption axis of the linear polarizer; and

When the circularly polarizing plate is observed from one face thereof, the direction of the slow axis of the λ/2 wave plate shifts counterclockwise by 15° from the direction of the polarized light absorption axis of the linear polarizer and the direction of the slow axis of the λ/4 wave plate shifts counterclockwise by 75° from the direction of the polarized light absorption axis of the linear polarizer.

As the linear polarizer, a known polarizer used for a device such as a liquid crystal display device and other optical devices may be used. Examples of the linear polarizer may include a linear polarizer obtained by subjecting a polyvinyl alcohol film to adsorption treatment with iodine or a dichroic dye, and then uniaxially stretching the film in a boric acid bath; and a linear polarizer obtained by subjecting a polyvinyl alcohol film to adsorption treatment with iodine or a dichroic dye, stretching the film, and modifying a part of polyvinyl alcohol unit in the molecular chain into a polyvinylene unit. Other examples of the linear polarizer may include a polarizer having a function of separating polarized light into reflected light and transmitted light, such as a grid polarizer, a multi-layer polarizer, and a cholesteric liquid crystal polarizer. Among these, it is preferable that the linear polarizer is a polarizer containing polyvinyl alcohol.

When natural light is made incident on the linear polarizer, only one polarized light is transmitted. The degree of polarization of the linear polarizer is not particularly limited, and is preferably 98% or more, and more preferably 99% or more.

The thickness of the linear polarizer is preferably 5 μm to 80 μm.

As the adhesion layer, a layer obtained by curing a curable adhesive may be used. As the curable adhesive, a thermosetting adhesive may be used. A photocurable adhesive is preferably used. As the photocurable adhesive, a photocurable adhesive containing a polymer or a reactive monomer may be used. The adhesive may contain one or more of a solvent, a photopolymerization initiator, and another additive, if necessary.

The photocurable adhesive is an adhesive that is capable of being cured by irradiation with light such as visible light, ultraviolet light, and infrared light. In particular, an adhesive that is capable of being cured by irradiation with ultraviolet light is preferable since an operation is simple.

In a preferable aspect, the photocurable adhesive contains 50% by weight or more of (meth)acrylate monomer having a hydroxyl group. Herein, when the “adhesive contains a monomer at a certain ratio”, the ratio of the monomer is the ratio of the total amount of the monomer that exists as it is and the monomer that has already become a portion of a polymer as a result of polymerization of the monomer.

Examples of the (meth)acrylate monomer having a hydroxyl group may include hydroxyalkyl (meth)acrylate such as 4-hydroxybutyl (meth)acrylate, 2-hydroxy-3-phenoxypropyl (meth)acrylate, 2-hydroxyethyl (meth)acrylate, 2-hydroxypropyl (meth)acrylate, 2-hydroxy-3-acryloyloxypropyl methacrylate, 2-hydroxyethyl acrylate, and 2-hydroxypropyl (meth)acrylate. One type thereof may be solely used, and two or more types thereof may also be used in combination at any ratio. When two or more types thereof are used in combination, the content is the total content.

Examples of the monomers other than the (meth)acrylate monomer having a hydroxyl group that may be contained in the photocurable adhesive may include a (meth)acrylate monomer having no monofunctional or multifunctional hydroxyl group and a compound having one or more epoxy groups per molecule.

The adhesive may further contain an optional component as long as the effects of the present invention are not significantly impaired. Examples of the optional component may include a photopolymerization initiator, a cross-linking agent, an inorganic filler, a polymerization inhibitor, a colored pigment, a dye, an anti-foaming agent, a leveling agent, a dispersant, a light diffusing agent, a plasticizer, an anti-static agent, a surfactant, a non-reactive polymer (inert polymer), a viscosity adjusting agent, and a near infrared absorbing material. One type thereof may be solely used, and two or more types thereof may also be used in combination at any ratio.

Examples of the photopolymerization initiator may include a radical polymerization initiator and a cationic polymerization initiator. Examples of the cationic polymerization initiator may include Irgacure 250 (diallyl iodonium, manufactured by BASF). Examples of the radical polymerization initiator may include Irgacure 184, Irgacure 819, and Irgacure 2959 (all manufactured by BASF).

The thickness of the adhesion layer is preferably 0.5 μm or more, and more preferably 1 μm or more, and is preferably 30 μm or less, more preferably 20 μm or less, and further preferably 10 μm or less. When the thickness of the adhesion layer falls within the aforementioned range, favorable adhesion can be achieved without impairing the optical properties of the optically anisotropic layered body.

The circularly polarizing plate may further contain an optional layer in combination with the optically anisotropic layer, the optically anisotropic layered body, the linear polarizer, and the adhesion layer.

For example, the circularly polarizing plate may contain a polarizer protective film layer on a surface of the linear polarizer. As the polarizer protective film layer, an optional transparent film layer may be used. In particular, a film layer of a resin having excellent transparency, mechanical strength, thermal stability, water shielding performance, and the like is preferable. Examples of such a resin may include an acetate resin such as triacetylcellulose, a polyester resin, a polyether sulfone resin, a polycarbonate resin, a polyamide resin, a polyimide resin, a chain olefin resin, a cyclic olefin resin, and a (meth)acrylic resin.

Examples of the optional layer that may be contained in the circularly polarizing plate may include a hardcoat layer such as an impact resistant polymethacrylate resin layer, a mat layer that improves slidability of the film, an antireflective layer, and an antifouling layer.

Only one layer of each of the layers may be provided or two or more layers thereof may be provided.

The circularly polarizing plate may be produced by a production method including bonding the optically anisotropic layer to the linear polarizer by the adhesion layer or a production method including bonding the optically anisotropic layered body to the linear polarizer by the adhesion layer.

Since in the circularly polarizing plate, the optically anisotropic layer has favorable reverse wavelength distribution, the circularly polarizing plate can uniformly exert a function of a λ/4 wave plate and a λ/2 wave plate within a wide wavelength range. Therefore, a polarized light state of light that passes through the circularly polarizing plate can be prevented from being altered from an appropriate state. Accordingly, in an image display device to which the circularly polarizing plate is applied (liquid crystal display device, organic electroluminescent display device, etc.), change of toning due to unintended change of polarized light state (phenomenon where a display surface looks blue or red) can be reduced.

It is preferable that the circularly polarizing plate is provided on a display surface of an organic electroluminescent display device as an anti-reflective film. By the provision of the circularly polarizing plate described above on a display surface of a display device so that a surface on a linear polarizer side faces a visual recognition side, light which has entered from the outside of the device can be prevented from exiting the device after reflection in the device. As a result, undesired phenomena such as glare on the display surface of the display device can be suppressed.

Specifically, when light is incident from the outside of the device, only a part of linearly polarized light passes through the linear polarizer, which then passes through the optically anisotropic layer or the optically anisotropic layered body, to become circularly polarized light. The circularly polarized light herein includes elliptically polarized light as long as an anti-reflection function is substantially exhibited. The circularly polarized light is reflected by a component that reflects light in the display device (reflection electrode in the organic electroluminescent element, etc.), and again passes through the optically anisotropic layer or the optically anisotropic layered body, to become linearly polarized light having a polarization axis in a direction orthogonal to the polarization axis of the linearly polarized light that has entered. Thus, the linearly polarized light does not pass through the liner polarizer. Accordingly, the anti-reflection function is achieved. In particular, since the optically anisotropic layer described above has favorable reverse wavelength distribution, the anti-reflective function at a broadband region is achieved.

Further, in the circularly polarizing plate having the optically anisotropic layered body, the phase difference layer exerts an optical compensation function suitable for light entered into the display surface. Therefore, when the circularly polarizing plate having the optically anisotropic layered body is provided in the display device as an anti-reflective film, reflection of outside light as viewed not only in a front direction of the display surface but also in an inclined direction of the display surface can be effectively suppressed.

### EXAMPLES

Hereinafter, the present invention will be specifically described with reference to Examples. However, the present invention is not limited to Examples described below. The present invention may be freely modified and practiced without departing from the scope of claims of the present invention and the scope of their equivalents.

Unless otherwise specified, “%” and “part(s)” that represent an amount in the following description are on the basis of weight. Unless otherwise specified, operations described below were performed under conditions of normal temperature and normal pressure in an atmospheric air.

[Evaluation Methods]

### [Method for Measuring Residual Monomer Ratio of Optically Anisotropic Layer]

A photopolymerizable liquid crystal compound used in each of Examples and Comparative Examples was dissolved in 1,3-dioxolane as a solvent, to obtain solutions having various concentrations for drawing a calibration curve. The solutions were each subjected to HPLC, to draw a calibration curve.

From the optically anisotropic layer transfer body obtained in each of Examples and Comparative Examples, an optically anisotropic layer with a size of 10 cm×10 cm was excised with a spatula, put in a vial, and weighed. Further, 1 g of 1,3-dioxolane was added thereto as a solvent, and the mixture was allowed to stand for 24 hours, and filtered through a 0.45-μm filter one time, to extract an unreacted monomer. Thus, an extract was obtained. The obtained extract was analyzed by HPLC, and the measurement result was compared with the calibration curve. Thus, the residual monomer ratio in the optically anisotropic layer was determined.

Conditions for HPLC are as follows.

Column: LC1200 (manufactured by Agilent Technologies)

Column temperature: 40° C.

Carrier (water:acetonitrile)

Linear concentration gradient from 0 minute (water:acetonitrile=5:95) to 5 minutes (water:acetonitrile=0:100), and additional 25 minutes (water:acetonitrile=0:100)

Elution time of residual monomer: approximately 13.2 minutes

[Method for Measuring Dichroic Ratio of Absorbance]

The dichroic ratio of absorbance of each optically anisotropic layer was measured by the following procedure using a measurement device including a spectrophotometer (“V-7200” manufactured by JASCO Corporation) and an automated absolute reflectance measurement unit (“VAR-7020” manufactured by JASCO Corporation) in combination.

As measurement of only a single layer of optically anisotropic layer is difficult, an optically anisotropic layer transfer body having a substrate film and an optically anisotropic layer that was obtained in each of Examples and Comparative Examples was prepared as a sample. The optically anisotropic layer transfer body was attached to the measurement device so that an S polarized light direction of the measurement device was parallel to the orientation direction of the optically anisotropic layer. An obliquely stretched ZEONOR film used as the substrate film of the optically anisotropic layer transfer body does not have absorption at a wavelength longer than 230 nm. Therefore, the absorbance at a wavelength longer than 230 nm can be regarded as the absorbance of the optically anisotropic layer. By performing the measurement, the absorbance for S polarized light was determined as the “absorbance for polarized light parallel to the orientation direction of the optically anisotropic layer” and the absorbance for P polarized light was determined as the “absorbance for polarized light perpendicular to the orientation direction of the optically anisotropic layer”. The dichroic ratio of absorbance was calculated from the ratio of absorbances at local maximum absorption wavelengths of a main chain and a side chain within each wavelength range.

[Method for Measuring in-Plane Retardation and Method for Evaluating Reverse Wavelength Distribution]

The in-plane retardation of the optically anisotropic layer obtained in each of Examples and Comparative Examples was measured by the following procedure using a phase difference meter (manufactured by Axometrics, Inc.).

The optically anisotropic layer of the optically anisotropic layer transfer body was bonded to a slide glass with a pressure sensitive adhesive (pressure sensitive adhesive: “CS9621T” manufactured by Nitto Denko Corporation). After that, the substrate film was peeled off, to obtain a sample having the slide glass and the optically anisotropic layer. Using this sample, in-plane retardations Re(450), Re(550), and Re(650) of the optically anisotropic layer were measured by the phase difference meter.

When the measured in-plane retardations Re(450), Re(550), and Re(650) of the optically anisotropic layer satisfy the formulae (3) and (4) described above, the reverse wavelength distribution of the optically anisotropic layer is evaluated to be “good”. When the in-plane retardations Re(450), Re(550), and Re(650) of the optically anisotropic layer do not satisfy either one or both of the formulae (3) and (4) described above, the reverse wavelength distribution of the optically anisotropic layer is evaluated to be “poor”.

[Method for Evaluating Optically Anisotropic Layer after Durability Test]

A part of an optically anisotropic transfer body obtained in each of Examples and Comparative Examples was cut out. Using the cut-out part, “dichroic ratio of absorbance” and “in-plane retardation” before a durability test of the optically anisotropic layer were measured by the methods described above.

After the measurement, the optically anisotropic transfer body was placed in a thermo-hygrostat bath of 85° C. and 85%, and allowed to stand for 250 hours in a durability test.

After the durability test, the optically anisotropic transfer body was taken out of the thermo-hygrostat bath. Using the optically anisotropic transfer body that was taken out, “dichroic ratio of absorbance” and “in-plane retardation” after the durability test of the optically anisotropic layer were measured by the methods described above. Values before and after the durability test were compared, and whether the optically anisotropic layer was durable to the durability test was confirmed.

### Example 1

### (1-1. Preparation of Liquid Crystal Composition)

100 parts by weight of a photopolymerizable liquid crystal compound LCK1 represented by the following formula (B1) (CN point: 96° C.), 3 parts by weight of a photopolymerization initiator (“Irgacure 379EG” available from BASF), and 0.3 parts by weight of a surfactant (“MEGAFACE F-562” available from DIC Corporation) were mixed. To the mixture, a mixed solvent of cyclopentanone and 1,3-dioxolane (weight ratio of cyclopentanone:1,3-dioxolane=4:6) was added as a dilution solvent so that the solid content was 22% by weight. Dissolution was achieved by heating the mixture to 50° C. The resulting mixture was subjected to filtration through a membrane filter with a pore diameter of 0.45 μm to obtain a liquid crystal composition.

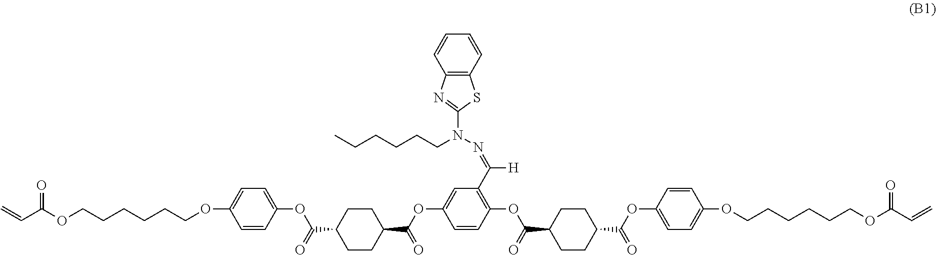 [SMILES: C=CC(=O)OCCCCCCOc1ccc(OC(=O)[C@H]2CC[C@H](C(=O)Oc3ccc(OC(=O)[C@H]4CC[C@H](C(=O)Oc5ccc(OCCCCCCOC(=O)C=C)cc5)CC4)c(/C=N\N(CCCCCC)c4nc5ccccc5s4)c3)CC2)cc1]

(1-2. Production and Evaluation of Optically Anisotropic Layer Transfer Body for Measurement of Residual Monomer Ratio and in-Plane Retardation)

As a substrate film, a long-length obliquely stretched film formed of a resin containing an alicyclic structure-containing polymer (“obliquely stretched ZEONOR film” manufactured by ZEON Corporation, glass transition temperature (Tg) of the resin: 126° C., thickness: 47 μm, in-plane retardation at a wavelength of 550 nm: 141 nm, stretching direction: direction at 45° relative to width direction) was prepared.

The liquid crystal composition obtained in Step (1-1) was applied onto the substrate film by a spin coater to form a layer of the liquid crystal composition. The thickness of the layer of the liquid crystal composition was adjusted so that the thickness of an optically anisotropic layer to be obtained was about 2.3 μm.

The layer of the liquid crystal composition was then dried in an oven of 110° C. for about 4 minutes to evaporate the solvent in the liquid crystal composition. At the same time, the photopolymerizable liquid crystal compound contained in the liquid crystal composition was oriented in the stretching direction of the substrate film.

Subsequently, the layer of the liquid crystal composition was irradiated with ultraviolet light by using an ultraviolet irradiation device. This irradiation with ultraviolet light was performed while the substrate film was fixed on an SUS plate heated to 60° C. by a tape in a nitrogen atmosphere. By the irradiation with ultraviolet light, the layer of the liquid crystal composition was cured, to obtain an optically anisotropic layer transfer body having the optically anisotropic layer and the substrate film.

Using the optically anisotropic layer transfer body, measurement of residual monomer ratio of the optically anisotropic layer, measurement of in-plane retardation of the optically anisotropic layer, and evaluation of reverse wavelength distribution of the optically anisotropic layer were performed by the methods described above.

### (1-3. Production and Evaluation of Optically Anisotropic Layer Transfer Body for Measurement of Absorbance)

An optically anisotropic layer transfer body was produced in the same manner as in the step (1-2) except that the thickness of the liquid crystal composition to be applied was changed so that the thickness of the optically anisotropic layer was 1.0 μm or less.

The absorbances ε₁ₘ, ε₁ₛ, ε₁ₘ, and ε₂ₛ of the optically anisotropic layer were measured by the method described above using the optically anisotropic layer transfer body, and the dichroic ratios of absorbance ε₁ₘ/ε₁ₛ and ε₂ₘ/ε₂ₛ were calculated.

### Example 2

Production of an optically anisotropic layer transfer body and evaluation of an optically anisotropic layer were performed in the same manner as in Example 1 except that the type of photopolymerizable liquid crystal compound was changed to a photopolymerizable liquid crystal compound LCK2 represented by the following formula (B2) (CN point: 102° C.)

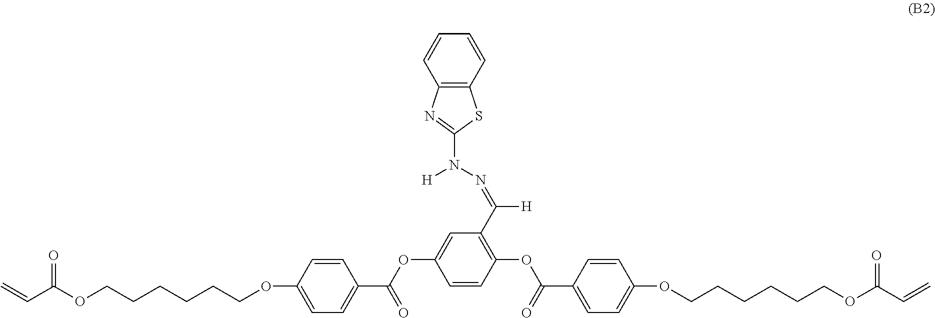 [SMILES: C=CC(=O)OCCCCCCOc1ccc(C(=O)Oc2ccc(OC(=O)c3ccc(OCCCCCCOC(=O)C=C)cc3)c(/C=N\Nc3nc4ccccc4s3)c2)cc1]

### Example 3

Production of an optically anisotropic layer transfer body and evaluation of an optically anisotropic layer were performed in the same manner as in Example 1 except that the type of photopolymerizable liquid crystal compound was changed to a photopolymerizable liquid crystal compound LCK3 represented by the following formula (B3) (CN point: 90° C.)

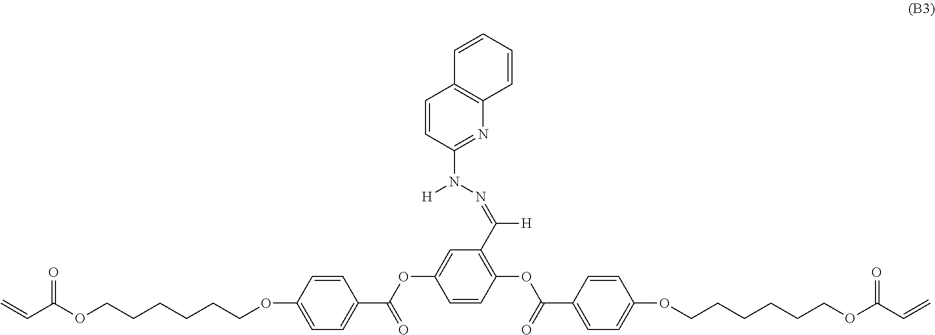 [SMILES: C=CC(=O)OCCCCCCOc1ccc(C(=O)Oc2ccc(OC(=O)c3ccc(OCCCCCCOC(=O)C=C)cc3)c(/C=N\Nc3ccc4ccccc4n3)c2)cc1]

### Example 4

Production of an optically anisotropic layer transfer body and evaluation of an optically anisotropic layer were performed in the same manner as in Example 1 except that the type of photopolymerizable liquid crystal compound was changed to a photopolymerizable liquid crystal compound LCK4 represented by the following formula (B4) (CN point: 110° C.)

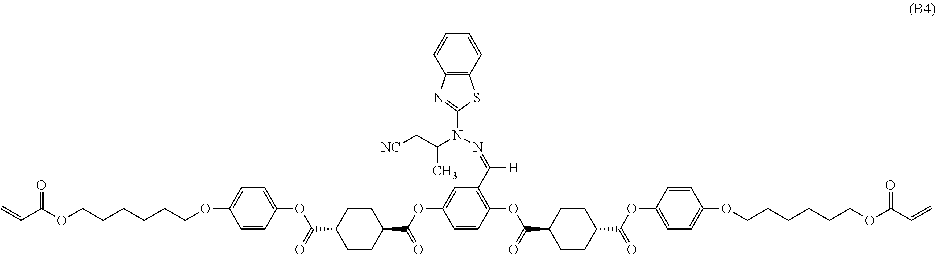 [SMILES: C=CC(=O)OCCCCCCOc1ccc(OC(=O)[C@H]2CC[C@H](C(=O)Oc3ccc(OC(=O)[C@H]4CC[C@H](C(=O)Oc5ccc(OCCCCCCOC(=O)C=C)cc5)CC4)c(/C=N\N(c4nc5ccccc5s4)C(C)CC#N)c3)CC2)cc1]

### Comparative Example 1

Production of an optically anisotropic layer transfer body and evaluation of an optically anisotropic layer were performed in the same manner as in Example 1 except that the type of photopolymerizable liquid crystal compound was changed to a photopolymerizable liquid crystal compound LCK5 represented by the following formula (B5) (CN point: 66° C.)

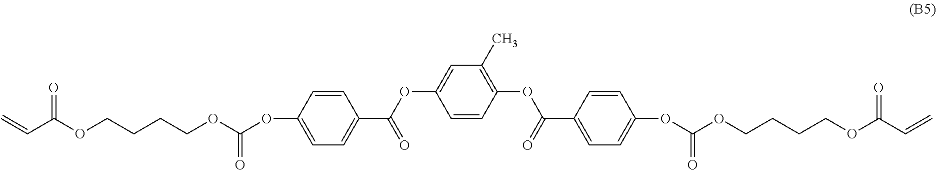 [SMILES: C=CC(=O)OCCCCOC(=O)Oc1ccc(C(=O)Oc2ccc(OC(=O)c3ccc(OC(=O)OCCCCOC(=O)C=C)cc3)c(C)c2)cc1]

### Comparative Example 2

Production of an optically anisotropic layer transfer body and evaluation of an optically anisotropic layer were performed in the same manner as in Example 1 except that irradiation with ultraviolet light in the steps (1-2) and (1-3) was performed while a substrate film was attached to an SUS plate of normal temperature of about 20° C. to 25° C. by using water in an air atmosphere.

### Results of Examples 1 to 4 and Comparative Examples 1 and 2

The results of Examples 1 to 4 and Comparative Examples 1 and 2 are shown in Table 1 described below. Abbreviations in Table 1 mean as follows.

Local maximum absorption wavelength (parallel): a local maximum absorption wavelength of an optically anisotropic layer for polarized light parallel to the orientation direction of the optically anisotropic layer

Local maximum absorption wavelength (perpendicular): a local maximum absorption wavelength of an optically anisotropic layer for polarized light perpendicular to the orientation direction of the optically anisotropic layer

TABLE 1
[Results of Examples and Comparative Examples]

| | | | | | Comp. | Comp. |
|---|---|---|---|---|---|---|
| | Ex. 1 | Ex. 2 | Ex. 3 | Ex. 4 | Ex. 1 | Ex. 2 |
| Liquid crystal compound | LCK1 | LCK2 | LCK3 | LCK4 | LCK5 | LCK1 |
| CN point | 96° C. | 102° C. | 90° C. | 110° C. | 66° C. | 96° C. |
| Residual monomer ratio | 10% | 10% | 10% | 10% | 10% | 30% |
| Thickness of optically | 0.88 | 1.5 | 0.58 | 0.58 | 1.14 | 1.0 |
| anisotropic layer for | | | | | | |
| measuring light absorbance | | | | | | |
| [μm] | | | | | | |
| Film temperature upon UV | 60° C. | 60° C. | 60° C. | 60° C. | 60° C. | 25° C. |
| curing | | | | | | |
| First wavelength range | | | | | | |
| Local maximum absorption | 250 nm | 260 nm | 250 nm | 250 nm | 255 nm | 250 nm |
| wavelength (parallel) | | | | | | |
| Local maximum absorption | 250 nm | 260 nm | 250 nm | 250 nm | 255 nm | 250 nm |
| wavelength (perpendicular) | | | | | | |
| Dichroic ratio before | 1.43 | 1.43 | 1.72 | 1.33 | 3.00 | 1.43 |
| durability test | | | | | | |
| Dichroic ratio after | 1.45 | 1.43 | 1.69 | 1.33 | 3.04 | 1.22 |
| durability test (ε₁ₘ/ε₁ₛ) | | | | | | |
| Second wavelength range | | | | | | |
| Local maximum absorption | 342 nm | 340 nm | 356 nm | 344 nm | None | 342 nm |
| wavelength (parallel) | | | | | | |
| Local maximum absorption | 353 nm | 340 nm | 356 nm | 347 nm | None | 353 nm |
| wavelength (perpendicular) | | | | | | |
| Dichroic ratio before | 0.30 | 0.65 | 0.53 | 0.43 | None | 0.30 |
| durability test | | | | | | |
| Dichroic ratio after | 0.29 | 0.65 | 0.53 | 0.44 | None | 0.75 |
| durability test (ε₂ₘ/ε₂ₛ) | | | | | | |
| Re (A450)/Re (A550) before | 0.78 | 0.90 | 0.89 | 0.93 | 1.09 | 0.81 |
| durability test | | | | | | |
| Re (A650)/Re (A550) before | 1.05 | 1.02 | 1.02 | 1.02 | 0.94 | 1.04 |
| durability test | | | | | | |
| Re (A450)/Re (A550) after | 0.79 | 0.92 | 0.91 | 0.95 | 1.09 | 0.98 |
| durability test | | | | | | |
| Re (A650)/Re (A550) after | 1.05 | 1.01 | 1.01 | 1.01 | 0.95 | 0.98 |
| durability test | | | | | | |
| Reverse wavelength | Good | Good | Good | Good | Poor | Poor |
| distribution after durability | | | | | (bad | |
| test | | | | | property | |
| | | | | | from | |
| | | | | | before) | |

### Discussion on Results of Examples 1 to 4 and Comparative Examples 1 and 2

As seen from Table 1, in Examples 1 to 4 in which the dichroic ratios ε₁ₘ/ε₁ₛ and ε₂ₘ/ε₂ₛ satisfy the formulae (1) and (2) and the residual monomer ratio is low, favorable wavelength distribution both before and after the durability test was successfully realized. The results confirm that an optically anisotropic layer having favorable reverse wavelength distribution can be realized by the present invention.

### Example 5

### [5-1. Preparation of Coating Composition for Formation of Phase Difference Layer]

A compound represented by the following formula (P1) (poly-9-vinyl carbazole; number-average molecular weight: about 1,100,000; manufactured by Aldrich) was added to N-methylpyrrolidinone as a solvent so that the solid content concentration was 12% by weight, and dissolution was achieved at room temperature, to obtain a coating composition for formation of a phase difference layer.

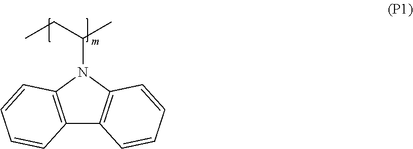

### [5-2. Production of Optically Anisotropic Layered Body]

An optically anisotropic layer transfer body having an optically anisotropic layer and a substrate film was prepared in the same manner as in the step (1-2) in Example 1. The in-plane retardation of the optically anisotropic layer was measured by a phase difference meter (manufactured by Axometrics, Inc.). The in-plane retardation at a wavelength of 550 nm was 139 nm. The coating composition for formation of a phase difference layer was applied onto the optically anisotropic layer of the optically anisotropic layer transfer body by using an applicator, to form a layer of the coating composition. After that, the layer of the coating composition was dried in an oven of 85° C. for about 10 minutes to evaporate the solvent contained in the layer of the coating composition. Thus, a phase difference layer having a thickness of about 10 μm was formed. The substrate film was then peeled off, to obtain the optically anisotropic layered body having the optically anisotropic layer and the phase difference layer.

The retardations Re(B550) and Rth(B550) at a wavelength of 550 nm in the phase difference layer of the optically anisotropic layered body were measured by a phase difference meter (manufactured by Axometrics, Inc.). As a result, the in-plane retardation Re(B550) was 1 nm, and the retardation Rth(B550) in the thickness direction was −59 nm.

### [5-3. Simulation of Organic Electroluminescent Display Device]

The anti-reflective function of the optically anisotropic layered body when the optically anisotropic layered body is attached to an organic electroluminescent display device was evaluated by simulation.

The simulation was performed using a software “LCD-MASTER” manufactured by Shintech. In the simulation, the organic electroluminescent display device was set as an organic electroluminescent display device provided with (a linear polarizer)/(an optically anisotropic layer)/(a phase difference layer)/(a reflection mirror). In this simulation, the angle formed between the absorption axis of the linear polarizer and the slow axis of the optically anisotropic layer was set to 45°.

The reflection luminance, reflection chromaticity, and change in reflection chromaticity of light incident at all angle from the linear polarizer side were calculated. The change in reflection chromaticity is a value represented by Δxy={(x1−x0)²+(y1−y0)²}^{(1/2)}, wherein (x0, y0) is the reflection chromaticity of light having entered into the linear polarizer in a normal direction and (x1, y1) is the reflection chromaticity of light having entered in an inclined direction.

Simulation results of the reflection luminance are shown in Table 2, and simulation results of the reflection chromaticity and change in reflection chromaticity are shown in Table 3. In Table 2, the values represent reflectivity (unit: %). In Table 3, x and y represent x value and y value of chromaticity coordinate, respectively. In Tables 2 and 3, simulation results of an organic electroluminescent display device provided with (a linear polarizer)/(an optically anisotropic layer)/(a reflection mirror) are also shown as Reference Example 1. In Example 5, reflection properties of light in the normal direction are not changed, and the reflection luminance and change in reflection chromaticity of light in the inclined direction are small, as compared with Reference Example 1. As seen from the results, the phase difference layer does not affect the reflection properties of light in the normal direction, and effectively suppresses the reflection of light in the inclined direction.

### Example 6

### [6-1. Production of Optically Anisotropic Layered Body]

As a support film, an unstretched film formed of a resin containing an alicyclic structure-containing polymer (“ZEONOR film” manufactured by ZEON Corporation) was prepared. The coating composition for formation of a phase difference layer produced in the step [5-1] of Example 5 was applied onto the support film using an applicator, to form a layer of the coating composition. After that, the layer of the coating composition was dried in an oven of 85° C. for about 10 minutes to evaporate the solvent contained in the layer of the coating composition. Thus, a phase difference layer having a thickness of about 10 μm was formed. The retardations Re(B550) and Rth(B550) at a wavelength of 550 nm in the phase difference layer were measured by using a phase difference meter (manufactured by Axometrics, Inc.). As a result, the in-plane retardation Re(B550) was 1 nm, and the retardation Rth(B550) in the thickness direction was −71 nm.

An optically anisotropic layer transfer body having an optically anisotropic layer and a substrate film was prepared in the same manner as in the step (1-2) in Example 1. The in-plane retardation of the optically anisotropic layer was measured by a phase difference meter (manufactured by Axometrics, Inc.). The in-plane retardation at a wavelength of 550 nm was 139 nm. The phase difference layer was bonded to the optically anisotropic layer of the optically anisotropic layer transfer body via an adhesive (“CS9621T” available from Nitto Denko Corporation), and the support film and the substrate film were peeled off. As a result, the optically anisotropic layered body having the optically anisotropic layer, an adhesion layer, and the phase difference layer was obtained.

### [6-2. Simulation of Organic Electroluminescent Display Device]

The anti-reflective function of the optically anisotropic layered body when the optically anisotropic layered body is attached to an organic electroluminescent display device was evaluated by simulation.

In the simulation, the same software as that in Example 5 was used, and an organic electroluminescent display device was set as an organic electroluminescent display device provided with (a linear polarizer)/(a phase difference layer)/(an adhesion layer)/(an optically anisotropic layer)/(a reflection mirror). In this simulation, the angle formed between the absorption axis of the linear polarizer and the slow axis of the optically anisotropic layer was set to 45°. The reflection luminance, reflection chromaticity, and change in reflection chromaticity of light incident at all angle from the linear polarizer side were calculated.

Simulation results of the reflection luminance are shown in Table 2, and simulation results of the reflection chromaticity and change in reflection chromaticity are shown in Table 3. In Example 6, reflection properties of light in the normal direction are not changed, and the reflection luminance and change in reflection chromaticity of light in the inclined direction are small, as compared with Reference Example 1. As seen from the results, the phase difference layer does not affect the reflection properties of light in the normal direction, and effectively suppresses the reflection of light in the inclined direction.

TABLE 2
[Reflection luminance]

| | Azimuth angle | Polar angle | Ref. | | |
|---|---|---|---|---|---|
| Incident direction | (°) | (°) | Ex. 1 | Ex. 5 | Ex. 6 |
| Normal direction | 0 | 0 | 0.18 | 0.18 | 0.18 |
| Inclined direction | 0 | 60 | 1.32 | 0.30 | 1.32 |
| | 45 | 60 | 3.96 | 1.70 | 1.68 |
| | 90 | 60 | 1.34 | 0.26 | 1.34 |
| | 135 | 60 | 4.44 | 1.74 | 1.59 |
| | 180 | 60 | 1.32 | 0.30 | 1.32 |

TABLE 3
[reflection chromaticity and change in reflection
chromaticity of light]

| | Azimuth | Polar | | | | | | | | | |
|---|---|---|---|---|---|---|---|---|---|---|---|
| Incident | angle | angle | Ref. Ex. 1 | | | Ex. 5 | | | Ex. 6 | | |
| direction | (°) | (°) | x | y | Δxy | x | y | Δxy | x | y | Δxy |
| Normal | 0 | 0 | 0.288 | 0.118 | — | 0.288 | 0.118 | — | 0.288 | 0.118 | — |
| direction | | | | | | | | | | | |
| Inclined | 0 | 60 | 0.315 | 0.300 | 0.184 | 0.269 | 0.132 | 0.023 | 0.315 | 0.300 | 0.184 |
| direction | 45 | 60 | 0.365 | 0.315 | 0.211 | 0.350 | 0.321 | 0.212 | 0.321 | 0.319 | 0.204 |
| | 90 | 60 | 0.318 | 0.303 | 0.187 | 0.273 | 0.124 | 0.016 | 0.318 | 0.303 | 0.187 |
| | 135 | 60 | 0.269 | 0.377 | 0.260 | 0.286 | 0.290 | 0.172 | 0.289 | 0.259 | 0.141 |
| | 180 | 60 | 0.315 | 0.300 | 0.184 | 0.269 | 0.132 | 0.023 | 0.315 | 0.300 | 0.184 |

### REFERENCE SIGN LIST

110 optically anisotropic layer
210 substrate film
220 layer of a liquid crystal composition
310 back roller
320 light source

1. An optically anisotropic layer obtained by curing a liquid crystal composition containing a photopolymerizable liquid crystal compound, wherein
a ratio of the photopolymerizable liquid crystal compound in the optically anisotropic layer is 25% by weight or less,
the optically anisotropic layer has a local maximum absorption wavelength for polarized light parallel to an orientation direction of the optically anisotropic layer and a local maximum absorption wavelength for polarized light perpendicular to the orientation direction of the optically anisotropic layer within each of a first wavelength range of 230 nm or more and less than 300 nm and a second wavelength range of 300 nm or more and 400 nm or less, and
an absorbance ε₁ₘ that is an absorbance of the optically anisotropic layer at the local maximum absorption wavelength for the polarized light parallel to the orientation direction of the optically anisotropic layer within the first wavelength range,
an absorbance ε₁ₛ that is an absorbance of the optically anisotropic layer at the local maximum absorption wavelength for the polarized light perpendicular to the orientation direction of the optically anisotropic layer within the first wavelength range,
an absorbance ε₂ₘ that is an absorbance of the optically anisotropic layer at the local maximum absorption wavelength for the polarized light parallel to the orientation direction of the optically anisotropic layer within the second wavelength range, and
an absorbance ε₂ₛ that is an absorbance of the optically anisotropic layer at the local maximum absorption wavelength for the polarized light perpendicular to the orientation direction of the optically anisotropic layer within the second wavelength range satisfy the following expressions (1) and (2):
1.30<ε₁ₘ/ε₁ₛ<1.70 (1), and
0.25<ε₂ₘ/ε₂ₛ<0.70 (2).

2. The optically anisotropic layer according to claim 1, wherein
an in-plane retardation Re(A450) of the optically anisotropic layer at a wavelength of 450 nm, an in-plane retardation Re(A550) of the optically anisotropic layer at a wavelength of 550 nm, and an in-plane retardation Re(A650) of the optically anisotropic layer at a wavelength of 650 nm satisfy the following expressions (3) and (4):
0.70<Re(A450)/Re(A550)<1.00 (3), and
1.00<Re(A650)/Re(A550)<1.20 (4).

3. The optically anisotropic layer according to claim 1, wherein
the photopolymerizable liquid crystal compound has a side chain mesogen represented by the following formula (A): 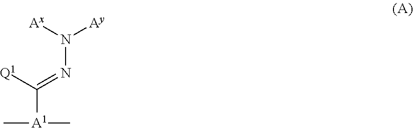
(in the Formula (A),
A^{x} is an organic group of 2 to 30 carbon atoms having at least one aromatic ring selected from the group consisting of an aromatic hydrocarbon ring and an aromatic heterocyclic ring,
A^{y} is a hydrogen atom, an alkyl group of 1 to 20 carbon atoms optionally having a substituent, an alkenyl group of 2 to 20 carbon atoms optionally having a substituent, a cycloalkyl group of 3 to 12 carbon atoms optionally having a substituent, an alkynyl group of 2 to 20 carbon atoms optionally having a substituent, —C(═O)—R³, —SO₂—R⁴, —C(═S)NH—R⁹, or an organic group of 2 to 30 carbon atoms having at least one aromatic ring selected from the group consisting of an aromatic hydrocarbon ring and an aromatic heterocyclic ring, wherein R³ is an alkyl group of 1 to 20 carbon atoms optionally having a substituent, an alkenyl group of 2 to 20 carbon atoms optionally having a substituent, a cycloalkyl group of 3 to 12 carbon atoms optionally having a substituent, or an aromatic hydrocarbon ring group of 5 to 12 carbon atoms; R⁴ is an alkyl group of 1 to 20 carbon atoms, an alkenyl group of 2 to 20 carbon atoms, a phenyl group or a 4-methylphenyl group; R⁹ is an alkyl group of 1 to 20 carbon atoms optionally having a substituent, an alkenyl group of 2 to 20 carbon atoms optionally having a substituent, a cycloalkyl group of 3 to 12 carbon atoms optionally having a substituent, or an aromatic group of 5 to 20 carbon atoms optionally having a substituent; the aromatic ring that A^{x} and A^{y} have may have a substituent; and A^{x} and A^{y} may form a ring together,
A¹ is a trivalent aromatic group optionally having a substituent, and
Q¹ is a hydrogen atom or an alkyl group of 1 to 6 carbon atoms optionally having a substituent).

4. The optically anisotropic layer according to claim 1, wherein the photopolymerizable liquid crystal compound is represented by the following Formula (I): 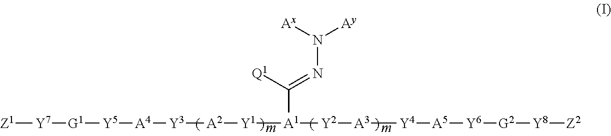
(in the Formula (I),
Y¹ to Y⁸ are each independently a chemical single bond, —O—, —S—, —O—C(═O)—, —C(═O)—O—, —O—C(═O)—O—, —NR¹—C(═O)—, —C(═O)—NR¹—, —O—C(═O)—NR¹—, —NR¹—C(═O)—O—, —NR¹—C(═O)—NR¹—, —O—NR¹—, or —NR¹—O—, wherein R¹ is a hydrogen atom or an alkyl group of 1 to 6 carbon atoms;
G¹ and G² are each independently a divalent aliphatic group of 1 to 20 carbon atoms optionally having a substituent; the aliphatic groups may have one or more per one aliphatic group of —O—, —S—, —O—C(═O)—, —C(═O)—O—, —O—C(═O)—O—, —NR²—C(═O)—, —C(═O)—NR²—, —NR²—, or —C(═O)— inserted therein; provided that a case where two or more —O— or —S— groups are each adjacently inserted are excluded, wherein R² is a hydrogen atom or an alkyl group of 1 to 6 carbon atoms;
Z¹ and Z² are each independently an alkenyl group of 2 to 10 carbon atoms optionally being substituted by a halogen atom;
A^{x} is an organic group of 2 to 30 carbon atoms having at least one aromatic ring selected from the group consisting of an aromatic hydrocarbon ring and an aromatic heterocyclic ring;
A^{y} is a hydrogen atom, an alkyl group of 1 to 20 carbon atoms optionally having a substituent, an alkenyl group of 2 to 20 carbon atoms optionally having a substituent, a cycloalkyl group of 3 to 12 carbon atoms optionally having a substituent, an alkynyl group of 2 to 20 carbon atoms optionally having a substituent, —C(═O)—R³, —SO₂—R⁴, —C(═S)NH—R⁹, or an organic group of 2 to 30 carbon atoms having at least one aromatic ring selected from the group consisting of an aromatic hydrocarbon ring and an aromatic heterocyclic ring, wherein R³ is an alkyl group of 1 to 20 carbon atoms optionally having a substituent, an alkenyl group of 2 to 20 carbon atoms optionally having a substituent, a cycloalkyl group of 3 to 12 carbon atoms optionally having a substituent, or an aromatic hydrocarbon ring group of 5 to 12 carbon atoms; R⁴ is an alkyl group of 1 to 20 carbon atoms, an alkenyl group of 2 to 20 carbon atoms, a phenyl group, or a 4-methylphenyl group; R⁹ is an alkyl group of 1 to 20 carbon atoms optionally having a substituent, an alkenyl group of 2 to 20 carbon atoms optionally having a substituent, a cycloalkyl group of 3 to 12 carbon atoms optionally having a substituent, or an aromatic group of 5 to 20 carbon atoms optionally having a substituent; the aromatic ring that A^{x} and A^{y} have may have a substituent; and A^{x} and A^{y} may form a ring together;
A¹ is a trivalent aromatic group optionally having a substituent;
A² and A³ are each independently a divalent alicyclic hydrocarbon group of 3 to 30 carbon atoms optionally having a substituent;
A⁴ and A⁵ are each independently a divalent aromatic group of 6 to 30 carbon atoms optionally having a substituent;
Q¹ is a hydrogen atom or an alkyl group of 1 to 6 carbon atoms optionally having a substituent; and
m is 0 or 1).

5. The optically anisotropic layer according to claim 1, wherein the photopolymerizable liquid crystal compound has a CN point of 25° C. or higher and 120° C. or lower.

6. The optically anisotropic layer according to claim 1, being a λ/4 wave plate.

7. An optically anisotropic layered body comprising the optically anisotropic layer according to claim 1, and a phase difference layer, wherein
a refractive index nx of the phase difference layer in a direction which gives a maximum refractive index among in-plane directions, a refractive index ny of the phase difference layer in a direction which is one of the in-plane directions and is orthogonal to the direction of the nx, and a refractive index nz of the phase difference layer in the thickness direction of the layer satisfy nz>nx≥ny.

8. The optically anisotropic layered body according to claim 7, wherein
the optically anisotropic layer is a λ/4 wave plate, and
an in-plane retardation Re(B550) of the phase difference layer at a wavelength of 550 nm and a retardation Rth(B550) in a thickness direction of the phase difference layer at a wavelength of 550 nm satisfy the following formulae (5) and (6):
Re(B550)≤10 nm (5), and
−100 nm≤Rth(B550)≤−20 nm (6).

9. A circularly polarizing plate comprising the optically anisotropic layer according to claim 1, and a linear polarizer.

10. A method for producing the optically anisotropic layer according to claim 1, comprising:
a step of applying the liquid crystal composition onto a substrate to obtain a layer of the liquid crystal composition;
a step of orienting the photopolymerization liquid crystal compound contained in the layer of the liquid crystal composition; and
a step of curing the liquid crystal composition.

11. A circularly polarizing plate comprising the optically anisotropic layered body according to claim 7, and a linear polarizer.
